(19) United States
(12) Patent Application Publication
(10) Pub. No.: US 2025/0321300 A1
(43) Pub. Date: Oct. 16, 2025

(54) MAGNETIC SENSOR, MAGNETIC FIELD DETECTION UNIT, POSITION DETECTION UNIT, LENS MODULE, IMAGING APPARATUS, AND METHOD OF MANUFACTURING MAGNETIC SENSOR

(71) Applicant: TDK Corporation, Tokyo (JP)

(72) Inventor: Takehiro ISODA, Tokyo (JP)

(73) Assignee: TDK Corporation, Tokyo (JP)

(21) Appl. No.: 19/079,759

(22) Filed: Mar. 14, 2025

(30) Foreign Application Priority Data
Apr. 11, 2024 (JP) 2024-064249

(51) Int. Cl. G01R 33/09; G01R 33/00

(52) U.S. Cl. CPC G01R 33/093; G01R 33/0052; G01R 33/0094

(57) ABSTRACT

A magnetic sensor includes a stacked structure including a first tier and a second tier. The first tier includes a magnetic yoke. The second tier includes a magnetic field detection element, and magnetic field generators that are disposed discretely along a first-axis direction and each apply a magnetic field to the magnetic field detection element. The first tier and the second tier are stacked in order in a second-axis direction intersecting the first-axis direction. The magnetic field detection element is interposed between two magnetic field generators in the first-axis direction. The magnetic yoke extends in the first-axis direction, and is adjacent to the magnetic field detection element in a third-axis direction in a plan view, the third-axis direction intersecting both the first-axis direction and the second-axis direction. Respective magnetization directions of the magnetic field generators are each inclined at less than 45 degrees with respect to the first-axis direction.

### CROSS-REFERENCE TO RELATED APPLICATIONS

The present application claims priority from Japanese Patent Application No. 2024-064249 filed on Apr. 11, 2024, the entire contents of which are hereby incorporated by reference.

### FIELD

The disclosure relates to a magnetic sensor and a method of manufacturing the magnetic sensor, and to a magnetic field detection unit, a position detection unit, a lens module, and an imaging apparatus that each include the magnetic sensor.

### BACKGROUND

A magnetic sensor including a magnetoresistive effect element has been used in various applications. As the magnetoresistive effect element, for example, a spin-valve magnetoresistive effect element may be used. There may be cases where a bias magnetic field is applied to the magnetoresistive effect element in the magnetic sensor for various purposes. For example, Japanese Unexamined Patent Application Publication No. 2022-077691 discloses a magnetic sensor including multiple bias magnetic field applying parts. The bias magnetic field applying parts apply respective bias magnetic fields in opposite directions to a first portion and a second portion of one free magnetic layer of a giant magnetoresistive effect element, in order to reduce an offset occurring on a resistance of the free magnetic layer. The bias magnetic field applying parts each have a structure in which a magnetic layer is interposed between two antiferromagnetic layers.

### SUMMARY

A magnetic sensor according to one embodiment of the disclosure includes a stacked structure including a first tier and a second tier. The first tier includes a magnetic yoke. The second tier includes a magnetic field detection element and magnetic field generators. The magnetic field generators are disposed discretely along a first-axis direction and each apply a magnetic field to the magnetic field detection element. The first tier and the second tier are stacked in order in a second-axis direction intersecting the first-axis direction. The magnetic field detection element is interposed between two of the magnetic field generators in the first-axis direction. The magnetic yoke extends in the first-axis direction, and is adjacent to the magnetic field detection element in a third-axis direction in a plan view as viewed in the second-axis direction, the third-axis direction intersecting both the first-axis direction and the second-axis direction. Respective magnetization directions of the magnetic field generators are each inclined at less than 45 degrees with respect to the first-axis direction.

A magnetic field detection unit according to one embodiment of the disclosure includes a magnetic sensor. The magnetic sensor includes a stacked structure including a first tier and a second tier. The first tier includes a magnetic yoke. The second tier includes a magnetic field detection element and magnetic field generators. The magnetic field generators are disposed discretely along a first-axis direction and each apply a magnetic field to the magnetic field detection element. The first tier and the second tier are stacked in order in a second-axis direction intersecting the first-axis direction. The magnetic field detection element is interposed between two of the magnetic field generators in the first-axis direction. The magnetic yoke extends in the first-axis direction, and is adjacent to the magnetic field detection element in a third-axis direction in a plan view as viewed in the second-axis direction, the third-axis direction intersecting both the first-axis direction and the second-axis direction. Respective magnetization directions of the magnetic field generators are each inclined at less than 45 degrees with respect to the first-axis direction.

A position detection unit according to one embodiment of the disclosure includes a magnetic sensor. The magnetic sensor includes a stacked structure including a first tier and a second tier. The first tier includes a magnetic yoke. The second tier includes a magnetic field detection element and magnetic field generators. The magnetic field generators are disposed discretely along a first-axis direction and each apply a magnetic field to the magnetic field detection element. The first tier and the second tier are stacked in order in a second-axis direction intersecting the first-axis direction. The magnetic field detection element is interposed between two of the magnetic field generators in the first-axis direction. The magnetic yoke extends in the first-axis direction, and is adjacent to the magnetic field detection element in a third-axis direction in a plan view as viewed in the second-axis direction, the third-axis direction intersecting both the first-axis direction and the second-axis direction. Respective magnetization directions of the magnetic field generators are each inclined at less than 45 degrees with respect to the first-axis direction.

A lens module according to one embodiment of the disclosure includes a magnetic sensor. The magnetic sensor includes a stacked structure including a first tier and a second tier. The first tier includes a magnetic yoke. The second tier includes a magnetic field detection element and magnetic field generators. The magnetic field generators are disposed discretely along a first-axis direction and each apply a magnetic field to the magnetic field detection element. The first tier and the second tier are stacked in order in a second-axis direction intersecting the first-axis direction. The magnetic field detection element is interposed between two of the magnetic field generators in the first-axis direction. The magnetic yoke extends in the first-axis direction, and is adjacent to the magnetic field detection element in a third-axis direction in a plan view as viewed in the second-axis direction, the third-axis direction intersecting both the first-axis direction and the second-axis direction. Respective magnetization directions of the magnetic field generators are each inclined at less than 45 degrees with respect to the first-axis direction.

An imaging apparatus according to one embodiment of the disclosure includes a lens module. The lens module includes a magnetic sensor. The magnetic sensor includes a stacked structure including a first tier and a second tier. The first tier includes a magnetic yoke. The second tier includes a magnetic field detection element and magnetic field generators. The magnetic field generators are disposed discretely along a first-axis direction and each apply a magnetic field to the magnetic field detection element. The first tier and the second tier are stacked in order in a second-axis direction intersecting the first-axis direction. The magnetic field detection element is interposed between two of the magnetic field generators in the first-axis direction. The magnetic yoke extends in the first-axis direction, and is adjacent to the magnetic field detection element in a third-axis direction in a plan view as viewed in the second-axis direction, the third-axis direction intersecting both the first-axis direction and the second-axis direction. Respective magnetization directions of the magnetic field generators are each inclined at less than 45 degrees with respect to the first-axis direction.

A magnetic sensor according to one embodiment of the disclosure includes a magnetic yoke, a magnetic field detection element, and magnetic field generators. The magnetic field generators are disposed discretely along a first-axis direction and each apply a magnetic field to the magnetic field detection element. The magnetic field detection element is interposed between two of the magnetic field generators in the first-axis direction. The magnetic field generators each include an exchange-coupled bias structure including a ferromagnetic body and an antiferromagnetic body, the antiferromagnetic body being in contact with and exchange-coupled to the ferromagnetic body. The magnetic yoke extends in the first-axis direction. Respective magnetization directions of the magnetic field generators are each inclined at less than 45 degrees with respect to the first-axis direction.

A magnetic field detection unit according to one embodiment of the disclosure includes a magnetic sensor. The magnetic sensor includes a magnetic yoke, a magnetic field detection element, and magnetic field generators. The magnetic field generators are disposed discretely along a first-axis direction and each apply a magnetic field to the magnetic field detection element. The magnetic field detection element is interposed between two of the magnetic field generators in the first-axis direction. The magnetic field generators each include an exchange-coupled bias structure including a ferromagnetic body and an antiferromagnetic body, the antiferromagnetic body being in contact with and exchange-coupled to the ferromagnetic body. The magnetic yoke extends in the first-axis direction. Respective magnetization directions of the magnetic field generators are each inclined at less than 45 degrees with respect to the first-axis direction.

A position detection unit according to one embodiment of the disclosure includes a magnetic sensor. The magnetic sensor includes a magnetic yoke, a magnetic field detection element, and magnetic field generators. The magnetic field generators are disposed discretely along a first-axis direction and each apply a magnetic field to the magnetic field detection element. The magnetic field detection element is interposed between two of the magnetic field generators in the first-axis direction. The magnetic field generators each include an exchange-coupled bias structure including a ferromagnetic body and an antiferromagnetic body, the antiferromagnetic body being in contact with and exchange-coupled to the ferromagnetic body. The magnetic yoke extends in the first-axis direction. Respective magnetization directions of the magnetic field generators are each inclined at less than 45 degrees with respect to the first-axis direction.

A lens module according to one embodiment of the disclosure includes a magnetic sensor. The magnetic sensor includes a magnetic yoke, a magnetic field detection element, and magnetic field generators. The magnetic field generators are disposed discretely along a first-axis direction and each apply a magnetic field to the magnetic field detection element. The magnetic field detection element is interposed between two of the magnetic field generators in the first-axis direction. The magnetic field generators each include an exchange-coupled bias structure including a ferromagnetic body and an antiferromagnetic body, the antiferromagnetic body being in contact with and exchange-coupled to the ferromagnetic body. The magnetic yoke extends in the first-axis direction. Respective magnetization directions of the magnetic field generators are each inclined at less than 45 degrees with respect to the first-axis direction.

An imaging apparatus according to one embodiment of the disclosure includes a lens module. The lens module includes a magnetic sensor. The magnetic sensor includes a magnetic yoke, a magnetic field detection element, and magnetic field generators. The magnetic field generators are disposed discretely along a first-axis direction and each apply a magnetic field to the magnetic field detection element. The magnetic field detection element is interposed between two of the magnetic field generators in the first-axis direction. The magnetic field generators each include an exchange-coupled bias structure including a ferromagnetic body and an antiferromagnetic body, the antiferromagnetic body being in contact with and exchange-coupled to the ferromagnetic body. The magnetic yoke extends in the first-axis direction. Respective magnetization directions of the magnetic field generators are each inclined at less than 45 degrees with respect to the first-axis direction.

A method of manufacturing a magnetic sensor according to one embodiment of the disclosure includes: forming a magnetic yoke extending in a first-axis direction; forming a magnetic field detection element; forming a first magnetic field generator and a second magnetic field generator to be each positioned adjacent to the magnetic yoke in a second-axis direction intersecting the first-axis direction, and to allow the magnetic field detection element to be interposed between the first magnetic field generator and the second magnetic field generator in the first-axis direction; magnetizing the first magnetic field generator by applying a first magnetic field to the first magnetic field generator in a first magnetization direction different from the first-axis direction, while heating the first magnetic field generator by applying first laser light selectively to the first magnetic field generator alone, of the first and second magnetic field generators; and magnetizing the second magnetic field generator by applying a second magnetic field to the second magnetic field generator in a second magnetization direction different from the first magnetization direction, while heating the second magnetic field generator by applying second laser light selectively to the second magnetic field generator alone, of the first and second magnetic field generators.

### BRIEF DESCRIPTION OF THE DRAWINGS

The accompanying drawings are included to provide a further understanding of the disclosure, and are incorporated in and constitute a part of this specification. The drawings illustrate example embodiments and, together with the specification, serve to explain the principles of the disclosure.

FIG. 1A is a plan diagram illustrating a plan configuration example of a magnetic sensor according to one example embodiment of the disclosure.

FIG. 1B is a first cross-sectional diagram illustrating a cross-sectional configuration example of the magnetic sensor illustrated in FIG. 1A.

FIG. 1C is a second cross-sectional diagram illustrating the cross-sectional configuration example of the magnetic sensor illustrated in FIG. 1A.

FIG. 1D is a third cross-sectional diagram illustrating the cross-sectional configuration example of the magnetic sensor illustrated in FIG. 1A.

FIG. 2A is a plan diagram schematically illustrating a step of a method of manufacturing the magnetic sensor illustrated in FIG. 1A.

FIG. 2B is a plan diagram schematically illustrating a step that follows the step of FIG. 2A.

FIG. 2C is a plan diagram schematically illustrating a step that follows the step of FIG. 2B.

FIG. 2D is a plan diagram schematically illustrating a step that follows the step of FIG. 2C.

FIG. 2E is a plan diagram schematically illustrating a step that follows the step of FIG. 2D.

FIG. 2F is a plan diagram schematically illustrating a step that follows the step of FIG. 2E.

FIG. 2G is a plan diagram schematically illustrating a step that follows the step of FIG. 2F.

FIG. 3 is a plan diagram illustrating a plan configuration example of a magnetic sensor according to a reference example.

FIG. 4 is a schematic plan diagram illustrating an overall configuration example of a magnetic field detection unit according to one example embodiment of the disclosure.

FIG. 5 is a circuit diagram illustrating a circuit configuration example of a magnetic field detection circuit included in the magnetic field detection unit illustrated in FIG. 4.

FIG. 6 is a characteristic chart illustrating an output characteristic of the magnetic field detection unit illustrated in FIG. 4.

FIG. 7 is a perspective diagram illustrating an overall configuration example of a magnetic compass according to one example embodiment of the disclosure.

FIG. 8A is a plan diagram illustrating a plan configuration example of a magnetic sensor to be mounted on the magnetic compass illustrated in FIG. 7.

FIG. 8B is a first cross-sectional diagram illustrating a cross-sectional configuration example of the magnetic sensor illustrated in FIG. 8A.

FIG. 8C is a second cross-sectional diagram illustrating the cross-sectional configuration example of the magnetic sensor illustrated in FIG. 8A.

FIG. 9 is a schematic perspective diagram illustrating an overall configuration example of an imaging apparatus according to one example embodiment of the disclosure.

### DETAILED DESCRIPTION

Regarding a magnetic field detection unit including a magnetic sensor, there may be cases where it is desired to detect a magnetic field including a component in a direction perpendicular to a plane of a substrate, through the use of a magnetoresistive effect element provided on the substrate. What is demanded of such a magnetic field detection unit is to achieve miniaturization and improvement in detection accuracy.

It is desirable to provide a magnetic sensor that makes it possible to accurately detect a magnetic field in a predetermined direction while achieving miniaturization, and to provide a magnetic field detection unit, a position detection unit, a lens module, and an imaging apparatus that each include such a magnetic sensor, and a method of manufacturing such a magnetic sensor.

In the following, some example embodiments of the disclosure are described in detail with reference to the accompanying drawings. Note that the following description is directed to illustrative examples of the disclosure and not to be construed as limiting to the disclosure. Factors including, without limitation, numerical values, shapes, materials, components, positions of the components, and how the components are coupled to each other are illustrative only and not to be construed as limiting to the disclosure. Further, elements in the following example embodiments which are not recited in a most-generic independent claim of the disclosure are optional and may be provided on an as-needed basis. The drawings are schematic and are not intended to be drawn to scale. Throughout the present specification and the drawings, elements having substantially the same function and configuration are denoted with the same reference numerals to avoid any redundant description. In addition, elements that are not directly related to any embodiment of the disclosure are unillustrated in the drawings. Note that the description is given in the following order.

### 1. First Example Embodiment

An example of a magnetic sensor including two yokes, multiple magnetoresistive effect elements, and multiple magnetic field generators.

### 2. Second Example Embodiment

An example of a magnetic field detection unit including multiple magnetic sensors.

### 3. Third Example Embodiment

An example of a magnetic compass including multiple magnetic sensors.

### 4. Fourth Example Embodiment and its Modification Example

An example of an imaging apparatus including a lens module with multiple magnetic sensors.

### 5. Other Modification Examples

### 1. First Example Embodiment

### [Configuration of Magnetic Sensor 1]

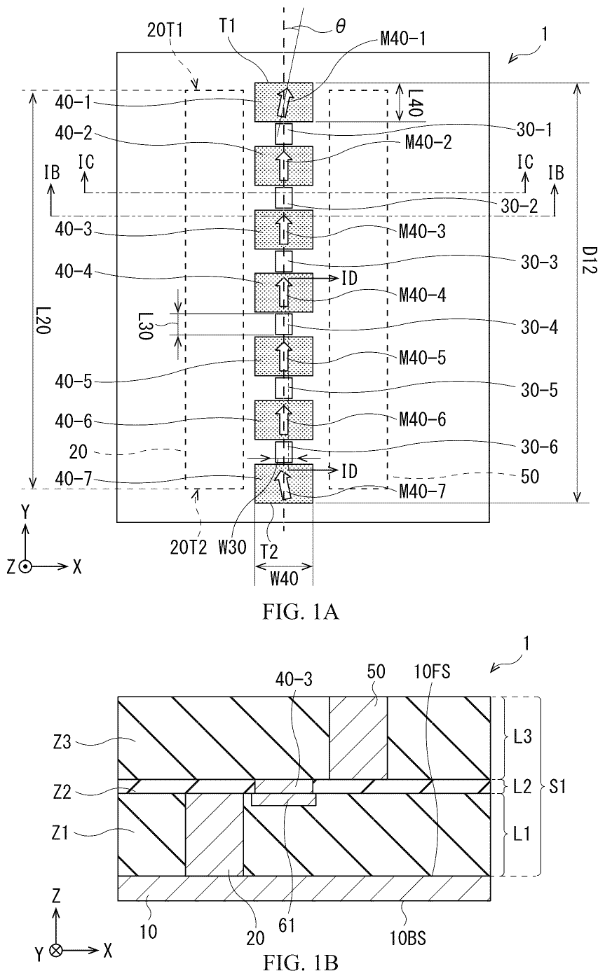

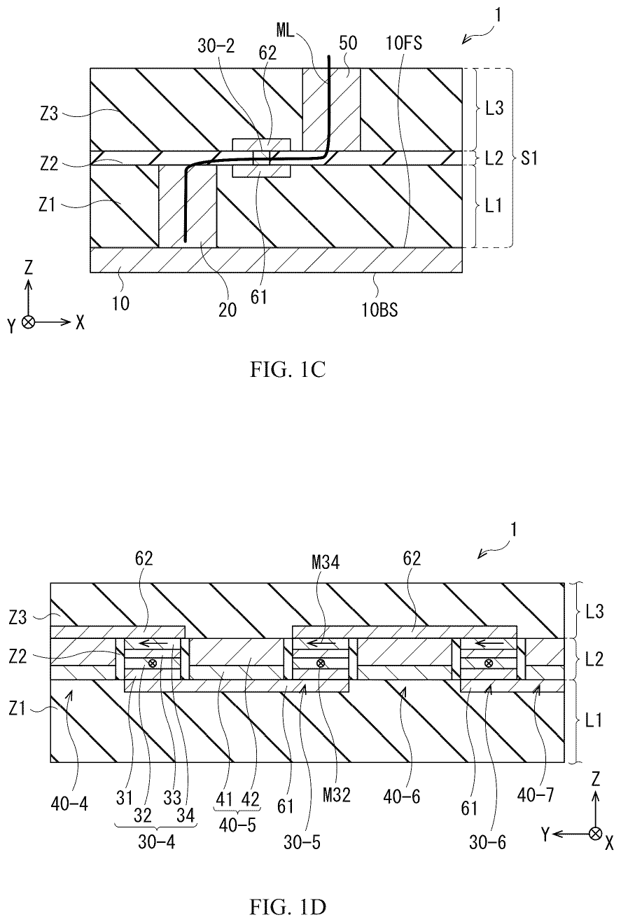

A description will be given first of a configuration of a magnetic sensor 1 according to a first example embodiment of the disclosure with reference to FIGS. 1A to 1D.

FIG. 1A is a plan diagram illustrating a plan configuration example of the magnetic sensor 1. FIG. 1B is a cross-sectional diagram illustrating a cross-sectional configuration example of the magnetic sensor 1 as viewed in an arrowed direction along line IB-IB illustrated in FIG. 1A. FIG. 1C is a cross-sectional diagram illustrating the cross-sectional configuration example of the magnetic sensor 1 as viewed in an arrowed direction along line IC-IC illustrated in FIG. 1A. FIG. 1D is a cross-sectional diagram illustrating the cross-sectional configuration example of the magnetic sensor 1 as viewed in an arrowed direction along line ID-ID illustrated in FIG. 1A.

An X-axis direction, a Y-axis direction, and a Z-axis direction illustrated in each of FIGS. 1A to 1D may respectively correspond to a specific but non-limiting example of a “third-axis direction”, a “first-axis direction”, and a “second-axis direction” in one embodiment of the disclosure. The X-axis direction, the Y-axis direction, and the Z-axis direction may be orthogonal to each other. As used herein, the term “orthogonal” is intended to encompass a state of intersection not only at geometrically exactly 90 degrees but also at 90 degrees plus or minus about 10 degrees, for example. Further, as viewed from any member or part as a reference, a +Z-side position or a +Z direction may be herein referred to as upper, above, or upward, and a −Z-side position or a −Z direction may be herein referred to as lower, below, or downward. Further, as viewed in a plane illustrated in FIG. 1A, for example, a direction from one or more magnetic field detection elements 30 toward an upper magnetic yoke 50 along the X-axis direction is herein defined as a +X direction, and a direction from the one or more magnetic field detection elements 30 toward a lower magnetic yoke 20 along the X-axis direction is herein defined as a −X direction. The one or more magnetic field detection elements 30, the upper magnetic yoke 50, and the lower magnetic yoke 20 will be described later.

As illustrated in FIGS. 1B to 1D, the magnetic sensor 1 may include a stacked structure S1 including, for example, a substrate 10, a first tier L1, a second tier L2, and a third tier L3. The first to third tiers L1 to L3 may be stacked in order in the +Z direction on the substrate 10. In other words, the +Z direction herein corresponds to a direction from the first tier L1 toward the third tier L3, and the −Z direction herein corresponds to a direction from the third tier L3 toward the first tier L1. The substrate 10 may have a front surface 10FS and a back surface 10BS. The first to third tiers L1 to L3 may be provided on an upper side of the front surface 10FS. In the configuration example illustrated in FIGS. 1A to 1D, the front surface 10FS and the back surface 10BS may each be a plane orthogonal to the Z-axis direction. In other words, the front surface 10FS and the back surface 10BS may each be an XY plane extending in both the X-axis direction and the Y-axis direction. The substrate 10 may be a support that supports multiple components included in each of the first to third tiers L1 to L3 described below. The substrate 10 may be a semiconductor substrate including a semiconductor material such as silicon (Si), or may be a magnetic shield including a soft magnetic material such as permalloy (NiFe).

The substrate 10 may correspond to a specific but non-limiting example of a “support” in one embodiment of the disclosure.

### [First Tier]

The first tier L1 may include the lower magnetic yoke 20, an insulating layer Z1, and multiple lower electrodes 61. The lower magnetic yoke 20 may be provided on a partial region of the front surface 10FS of the substrate 10. The lower magnetic yoke 20 may include, for example, a soft ferromagnetic material such as permalloy (NiFe). The lower magnetic yoke 20 may guide a magnetic field line ML of a Z-axis-direction component of a magnetic field targeted for detection toward the one or more magnetic field detection elements 30 to be described later. Hereinafter, the magnetic field targeted for detection will be referred to as a detection-target magnetic field. The lower magnetic yoke 20 extends in the Y-axis direction, and is disposed adjacent to the one or more magnetic field detection elements 30 in the X-axis direction in a plan view as viewed in the Z-axis direction. The lower magnetic yoke 20 may correspond to a specific but non-limiting example of a “magnetic yoke” in one embodiment of the disclosure. The insulating layer Z1 may be provided on a region, of the front surface 10FS, that surrounds the lower magnetic yoke 20. The insulating layer Z1 may include, for example, a nonmagnetic insulating material such as aluminum oxide (AlOₓ), aluminum nitride (AlN), or silicon oxide (SiOₓ). The lower electrodes 61 may be embedded in the insulating layer Z1, and may each be partly exposed in a top surface of the first tier L1, that is, a top surface of the insulating layer Z1 opposite to the front surface 10FS. The lower electrodes 61 may be separated from the lower magnetic yoke 20. The lower electrodes 61 may each be in contact with a bottom surface or bottom surfaces of one or two magnetic field detection elements 30, of the one or more magnetic field detection elements 30 to be described later, and may each be electrically coupled to the one or two magnetic field detection elements 30. The lower electrodes 61 may each include, for example, a highly electrically-conductive nonmagnetic material such as copper (Cu). Note that FIG. 1A omits the illustration of the lower electrodes 61 in order to increase visibility of the one or more magnetic field detection elements 30 and multiple magnetic field generators 40 to be described later.

### [Second Tier]

The second tier L2 may include the one or more magnetic field detection elements 30, the multiple magnetic field generators 40, and an insulating layer Z2. In the configuration example illustrated in FIG. 1A, the magnetic sensor 1 may include six magnetic field detection elements 30 (30-1 to 30-6) and seven magnetic field generators 40 (40-1 to 40-7). However, in any embodiment of the disclosure, the number of the magnetic field detection elements 30 and the number of the magnetic field generators 40 may each be freely chosen. The magnetic field generators 40 are disposed discretely along the Y-axis direction. The magnetic field generators 40 may each apply a bias magnetic field to one or more of the magnetic field detection elements 30. The bias magnetic field may be in a direction parallel to the Y-axis direction. In the present example embodiment, a direction from the magnetic field generator 40-7 toward the magnetic field generator 40-1 is defined as a +Y direction, and a direction from the magnetic field generator 40-1 toward the magnetic field generator 40-7 is defined as a −Y direction. In the present example embodiment, the magnetic field generators 40 may each apply the bias magnetic field in the +Y direction to one or more of the magnetic field detection elements 30. The magnetic field detection elements 30 are each interposed between two of the magnetic field generators 40 in the Y-axis direction. The magnetic field generators 40 and the magnetic field detection elements 30 may thus be alternately disposed along the Y-axis direction. The magnetic field generators 40 and the magnetic field detection elements 30 may be separated from each other. As illustrated in FIG. 1D, a spacing between every single magnetic field detection element 30 and two adjacent magnetic field generators 40 may be filled with the insulating layer Z2. The magnetic field detection elements 30 may be provided on the lower electrodes 61. The magnetic field detection elements 30 may be electrically coupled to the lower electrodes 61. As illustrated in FIG. 1A, respective magnetization directions M40 (M40-1 to M40-7) of the magnetic field generators 40 (40-1 to 40-7) are each inclined at less than 45 degrees with respect to the Y-axis direction. For example, the magnetization directions M40 (M40-1 to M40-7) may each substantially coincide with the Y-axis direction. Further, the magnetic field detection elements 30 and the magnetic field generators 40 may each be positioned not to overlap the lower magnetic yoke 20 in a plan view as viewed in the Z-axis direction.

The magnetic field detection elements 30 may each correspond to a specific but non-limiting example of a “magnetic field detection element” in one embodiment of the disclosure. The magnetic field generators 40 may correspond to a specific but non-limiting example of “magnetic field generators” in one embodiment of the disclosure.

As illustrated in FIG. 1A, the magnetic field generators 40 disposed discretely along the Y-axis direction may include the magnetic field generator 40-1 positioned at a first end in the Y-axis direction, and the magnetic field generator 40-7 positioned at a second end, opposite to the first end, in the Y-axis direction. The first end may be an end that is most toward a +Y side in the Y-axis direction, and the second end may be an end that is most toward a −Y side in the Y-axis direction. In the magnetic sensor 1, a distance D12 between a first edge T1 of the magnetic field generator 40-1 and a second edge T2 of the magnetic field generator 40-7 may be greater than or equal to a length L20 of the lower magnetic yoke 20 in the Y-axis direction. In other words, the length L20 of the lower magnetic yoke 20 may be less than or equal to the distance D12. For example, the length L20 of the lower magnetic yoke 20 may be a length from a +Y-side edge 20T1 of the lower magnetic yoke 20 to a −Y-side edge 20T2 of the lower magnetic yoke 20. The first edge T1 may be an edge, of the magnetic field generator 40-1, that is positioned farthest from the magnetic field generator 40-7. The second edge T2 may be an edge, of the magnetic field generator 40-7, that is positioned farthest from the magnetic field generator 40-1.

The magnetic field detection elements 30 may each be a magnetoresistive effect (MR) element, for example. The MR element may be a spin-valve MR element or an anisotropic magnetoresistive effect (AMR) element. When the magnetic field detection elements 30 are each the spin-valve MR element, the magnetic field detection elements 30 may each have a structure in which, as illustrated in FIG. 1D, for example, an antiferromagnetic layer 31, a magnetization pinned layer 32, a gap layer 33, and a magnetization free layer 34 are stacked in order. The magnetization pinned layer 32 may have a magnetization M32 pinned in a predetermined direction. The magnetization free layer 34 may have a magnetization M34 that changes direction in accordance with a direction of an applied magnetic field. For the present embodiment, a description will be given of an example case where the magnetic field detection elements 30 are each the spin-valve MR element. The magnetic field detection elements 30 may each be a tunneling magnetoresistive effect (TMR) element or a giant magnetoresistive effect (GMR) element. When the magnetic field detection elements 30 are each the TMR element, the gap layer may be a tunnel barrier layer. When the magnetic field detection elements 30 are each the GMR element, the gap layer may be a nonmagnetic electrically-conductive layer. The magnetic field detection elements 30 may each change in resistance value in accordance with an angle that the direction of the magnetization M34 of the magnetization free layer 34 forms with respect to the direction of the magnetization M32 of the magnetization pinned layer 32. In each of the magnetic field detection elements 30 of the present example embodiment, the direction of the magnetization M34 of the magnetization free layer 34 is rotatable in the XY plane. The magnetic field detection elements 30 as the MR elements each exhibit a minimum resistance value when the angle between the direction of the magnetization M34 of the magnetization free layer 34 and the direction of the magnetization M32 of the magnetization pinned layer 32 is 0 degrees, and each exhibit a maximum resistance value when the above-described angle is 180 degrees. For example, in the XY plane, a longitudinal direction of each of the magnetic field detection elements 30 may be along the Y-axis direction. In other words, in each of the magnetic field detection elements 30, the magnetization free layer 34 may have a shape anisotropy in the Y-axis direction and have an easy axis of magnetization along the Y-axis direction. Further, for example, the magnetization M32 of the magnetization pinned layer 32 in each of the magnetic field detection elements 30 may be in a direction along the X-axis direction orthogonal to the Y-axis direction. In the configuration example illustrated in FIG. 1D, the magnetization M32 may be in the +X direction.

For example, a length L30 of each of the magnetic field detection elements 30 in the Y-axis direction may be smaller than a length L40 of each of the magnetic field generators 40 in the Y-axis direction. One reason for this is that this helps to allow the magnetic field detection elements 30 to achieve an increased linearity of changes in electrical resistance value versus changes in intensity of the detection-target magnetic field. Further, a width W30 of each of the magnetic field detection elements 30 in the X-axis direction may be smaller than a width W40 of each of the magnetic field generators 40 in the X-axis direction, for example.

As illustrated in FIG. 1D, the magnetic field generators 40 may each have a stacked structure including, for example, an antiferromagnetic layer 41 and a ferromagnetic layer 42. The antiferromagnetic layer 41 and the ferromagnetic layer 42 may be in contact with and exchange-coupled to each other. Thus, the magnetic field generators 40 may each include an exchange-coupled bias structure.

The antiferromagnetic layer 41 may correspond to a specific but non-limiting example of an “antiferromagnetic body” in one embodiment of the disclosure. The ferromagnetic layer 42 may correspond to a specific but non-limiting example of a “ferromagnetic body” in one embodiment of the disclosure.

The ferromagnetic layer 42 may have an overall magnetization thereof. As used herein, the overall magnetization of the ferromagnetic layer 42 refers to a volume average of a vector sum of magnetic moments in units of atoms, crystal lattices, or the like in the entire ferromagnetic layer 42. Hereinafter, the overall magnetization of the ferromagnetic layer 42 will simply be referred to as a magnetization of the ferromagnetic layer 42.

The ferromagnetic layer 42 may include a single-layer film or a multilayer film. The ferromagnetic layer 42 may include a ferromagnetic material containing one or more elements selected from, for example, cobalt (Co), iron (Fe), and nickel (Ni). Non-limiting examples of such a ferromagnetic material may include CoFe, CoFeB, and CoNiFe.

The antiferromagnetic layer 41 may include an antiferromagnetic material such as IrMn or PtMn.

In each of the magnetic field generators 40, a direction of the magnetization of the ferromagnetic layer 42 may be defined by the exchange coupling between the antiferromagnetic layer 41 and the ferromagnetic layer 42. This helps to allow the magnetic field generators 40 to have high immunity to disturbance magnetic fields. The direction of the magnetization of the ferromagnetic layer 42 may coincide with the magnetization direction M40.

As viewed in the Y-axis direction, all or a part of the magnetization free layer 34 of each of the magnetic field detection elements 30 may overlap all or a part of the ferromagnetic layer 42 of each of two magnetic field generators 40 that are positioned to allow relevant one of the magnetic field detection elements 30 to be interposed therebetween in the Y-axis direction. In the configuration example illustrated in FIG. 1D, all of the magnetization free layer 34 may overlap a part of the ferromagnetic layer 42 as viewed in the Y-axis direction.

### [Third Tier]

The third tier L3 may include the upper magnetic yoke 50, an insulating layer Z3, and multiple upper electrodes 62. As illustrated in FIGS. 1A to 1C, the upper magnetic yoke 50 may extend in the Y-axis direction, and may be positioned to overlap none of the lower magnetic yoke 20, the magnetic field detection elements 30, the magnetic field generators 40, etc. in a plan view as viewed in the Z-axis direction. For example, the upper magnetic yoke 50 may be provided in a region on a side of the magnetic field detection elements 30 and the magnetic field generators 40 opposite in the X-axis direction to the region where the lower magnetic yoke 20 is provided. The upper magnetic yoke 50 may include, for example, a soft ferromagnetic material such as permalloy (NiFe), and may guide the magnetic field line ML toward the magnetic field detection elements 30. The insulating layer Z3 may be provided in a region surrounding the upper magnetic yoke 50. The insulating layer Z3 may include, for example, a nonmagnetic insulating material such as aluminum oxide (AlOₓ), aluminum nitride (AlN), or silicon oxide (SiOₓ). The upper electrodes 62 may be embedded in the insulating layer Z3, and may each be partly exposed in a bottom surface of the third tier L3, that is, a surface, of the insulating layer Z3, that faces toward the magnetic field detection elements 30. The upper electrodes 62 may be separated from the upper magnetic yoke 50. The upper electrodes 62 may each be in contact with a top surface or top surfaces of one or two of the magnetic field detection elements 30 and electrically coupled to the one or two of the magnetic field detection elements 30. The upper electrodes 62 may each include, for example, a highly electrically-conductive nonmagnetic material such as copper (Cu). Note that FIG. 1A omits the illustration of the upper electrodes 62 in order to increase visibility of the magnetic field detection elements 30 and the magnetic field generators 40.

In the magnetic sensor 1, the magnetic field detection elements 30 arranged in the Y-axis direction may be electrically coupled in series to each other via the lower electrodes 61 and the upper electrodes 62. For example, one lower electrode 61 may be in contact with the respective bottom surfaces of two magnetic field detection elements 30 that are adjacent to each other in the Y-axis direction, and may electrically couple the two magnetic field detection elements 30 to each other. Further, one upper electrode 62 may be in contact with the respective top surfaces of two magnetic field detection elements 30 that are adjacent to each other in the Y-axis direction, and may electrically couple the two magnetic field detection elements 30 to each other. Note that a combination of two magnetic field detection elements 30 coupled to each other by one lower electrode 61 and a combination of two magnetic field detection elements 30 coupled to each other by one upper electrode 62 may be different from each other without exception. For example, as illustrated in FIG. 1D, the magnetic field detection element 30-5 may be electrically coupled to the magnetic field detection element 30-4 positioned on the +Y side of the magnetic field detection element 30-5 by one lower electrode 61, and may be electrically coupled to the magnetic field detection element 30-6 positioned on the −Y side of the magnetic field detection element 30-5 by one upper electrode 62. Note that the magnetic field generators 40 may each be in contact with either one lower electrode 61 or one upper electrode 62; however, the magnetic field generators 40 may each be disposed not to be in contact with both the lower electrode 61 and the upper electrode 62. The magnetic field generators 40 may be insulated from both the lower electrodes 61 and the upper electrodes 62.

### [Method of Manufacturing Magnetic Sensor 1]

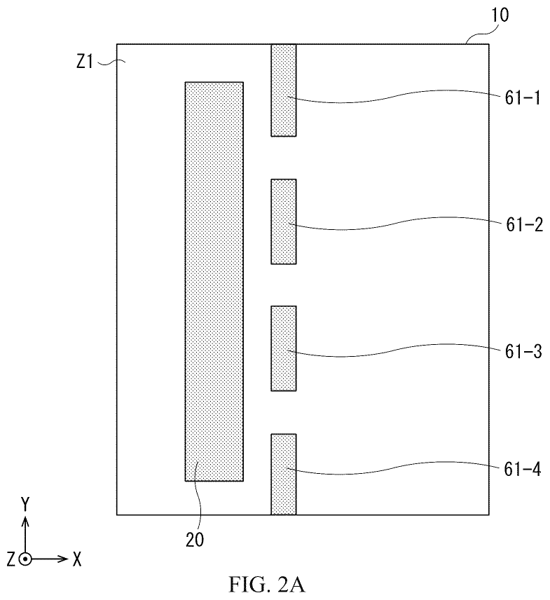

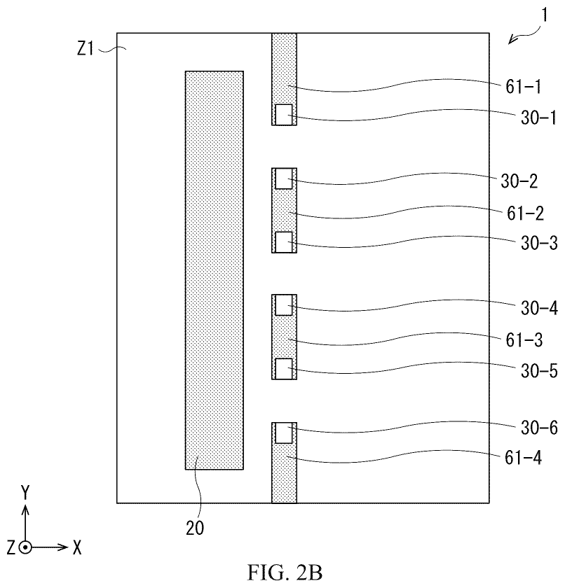

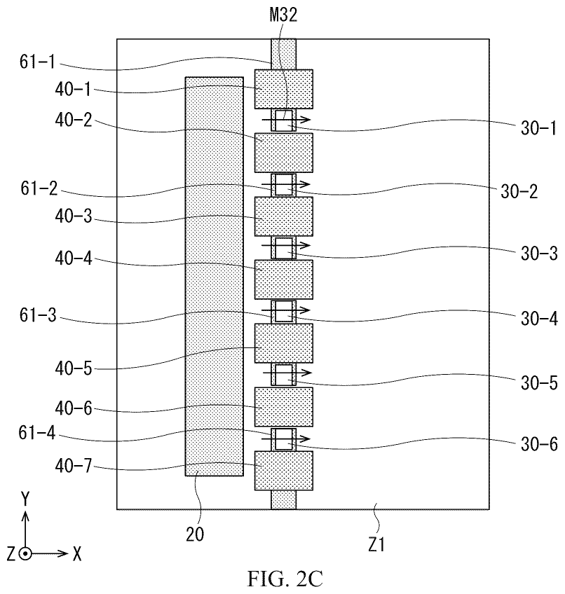

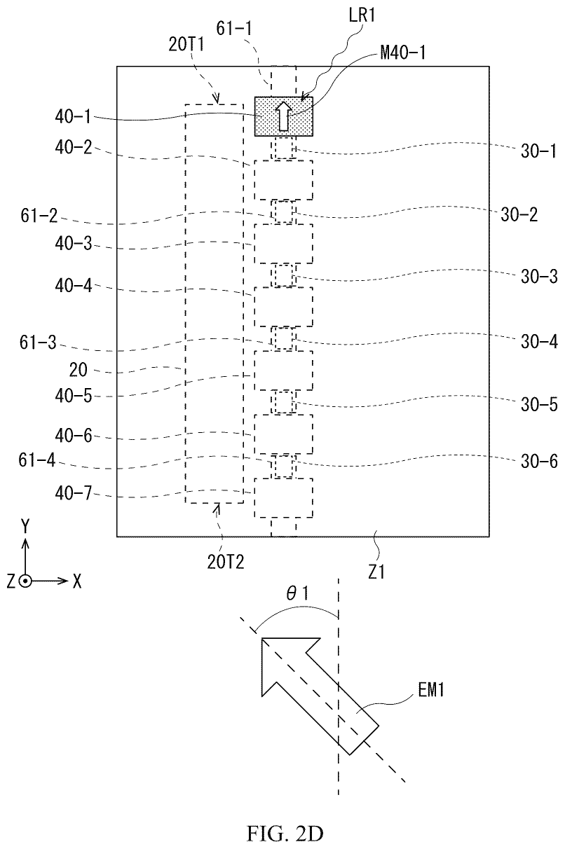

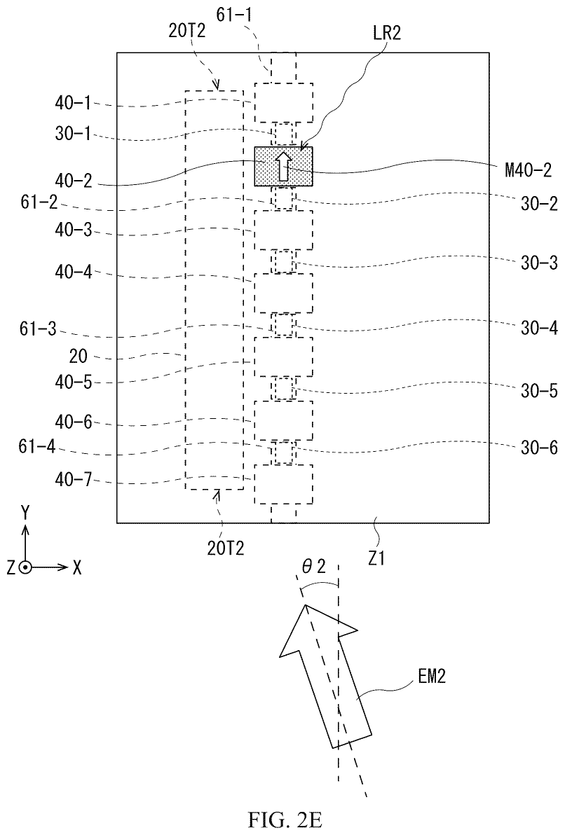

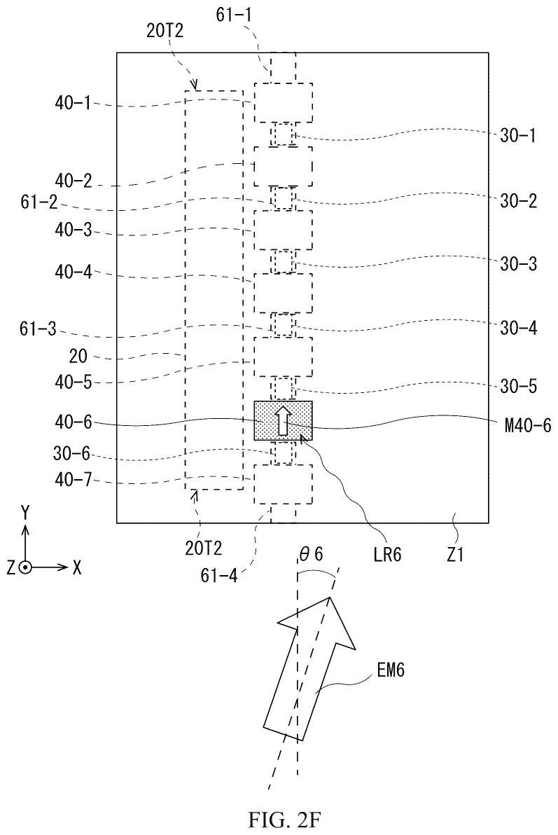

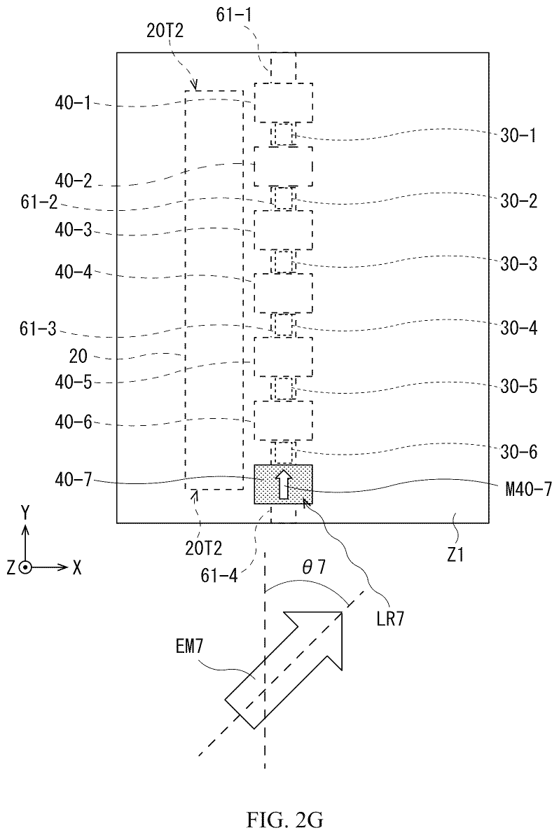

An example method of manufacturing the magnetic sensor 1 will now be described with reference to FIGS. 2A to 2G, as well as FIGS. 1A to 1D.

First, as illustrated in FIG. 2A, the lower magnetic yoke 20, the insulating layer Z1, and the lower electrodes 61 may each be formed on the substrate 10. In this step, the lower magnetic yoke 20 may be formed to extend in the Y-axis direction. The lower electrodes 61 may be arranged in the Y-axis direction at predetermined spacings. FIG. 2A illustrates an example case of forming four lower electrodes 61-1 to 61-4.

Thereafter, as illustrated in FIG. 2B, the magnetic field detection elements 30 may be formed to be adjacent to the lower magnetic yoke 20 in the X-axis direction. Here, one or two magnetic field detection elements 30 may be formed on each single lower electrode 61. For example, the magnetic field detection element 30-1 alone may be formed on the lower electrode 61-1 that is positioned most toward the +Y side of all the four lower electrodes 61-1 to 61-4, and the magnetic field detection element 30-6 alone may be formed on the lower electrode 61-4 that is positioned most toward the −Y side of all the four lower electrodes 61-1 to 61-4. Further, two magnetic field detection elements 30-2 and 30-3 may be formed on the lower electrode 61-2, and two magnetic field detection elements 30-4 and 30-5 may be formed on the lower electrode 61-3. In the step of forming the magnetic field detection elements 30-1 to 30-6, first, a layered film may be formed by stacking the antiferromagnetic layer 31, the magnetization pinned layer 32, the gap layer 33, and the magnetization free layer 34 in order on each of the lower electrodes 61 by sputtering, following which the layered film may be processed into a predetermined plan shape. Thereafter, laser irradiation may be performed on the layered film thus processed into the predetermined plan shape, while applying an external magnetic field to the layered film in the +X direction, for example. The direction of the magnetization M32 of the magnetization pinned layer 32 may thus be pinned in the +X direction.

Thereafter, as illustrated in FIG. 2C, the magnetic field generators 40 may be formed to allow each of the magnetic field detection elements 30 to be interposed between two magnetic field generators 40 in the Y-axis direction. For example, the magnetic field generators 40-1 to 40-7 may be formed to allow the magnetic field detection element 30-1 to be interposed between the magnetic field generators 40-1 and 40-2 in the Y-axis direction, allow the magnetic field detection element 30-2 to be interposed between the magnetic field generators 40-2 and 40-3 in the Y-axis direction, allow the magnetic field detection element 30-3 to be interposed between the magnetic field generators 40-3 and 40-4 in the Y-axis direction, allow the magnetic field detection element 30-4 to be interposed between the magnetic field generators 40-4 and 40-5 in the Y-axis direction, allow the magnetic field detection element 30-5 to be interposed between the magnetic field generators 40-5 and 40-6 in the Y-axis direction, and allow the magnetic field detection element 30-6 to be interposed between the magnetic field generators 40-6 and 40-7 in the Y-axis direction.

Thereafter, as illustrated in FIG. 2D, laser light LR1 may be applied selectively to the magnetic field generator 40-1 alone, of the magnetic field generators 40-1 to 40-7, to thereby heat the magnetic field generator 40-1. In applying the laser light LR1 selectively to the magnetic field generator 40-1, a mask may be used that has an opening only at a location corresponding to the magnetic field generator 40-1 in the XY plane, for example. Further, in some embodiments, the heating of the magnetic field generator 40-1 may be performed to cause the magnetic field generator 40-1 to be at a temperature exceeding a blocking temperature of the antiferromagnetic layer 41 included in the magnetic field generator 40-1. To the magnetic field generator 40-1 thus heated by irradiation with the laser light LR1, a magnetic field EM1 may be applied in a direction different from the Y-axis direction to thereby magnetize the magnetic field generator 40-1. The direction of the magnetic field EM1 may be a direction inclined toward a −X side by an angle θ1 with respect to the +Y direction as a reference direction, for example. The angle θ1 may be less than 45 degrees, for example. In some embodiments, the angle θ1 may be about 30 degrees. This helps to allow the magnetization direction M40-1 of the magnetic field generator 40-1 positioned in the vicinity of the edge 20T1 of the lower magnetic yoke 20 to be pinned substantially in the +Y direction. The laser light LR1 to be applied in pinning the magnetization direction M40-1 may be lower in intensity than laser light to be applied in pinning the direction of the magnetization of the magnetization pinned layer 32 of each of the magnetic field detection elements 30.

Thereafter, as illustrated in FIG. 2E, laser light LR2 may be applied selectively to the magnetic field generator 40-2 alone, of the magnetic field generators 40-1 to 40-7, to thereby heat the magnetic field generator 40-2. In applying the laser light LR2 selectively to the magnetic field generator 40-2, a mask may be used that has an opening only at a location corresponding to the magnetic field generator 40-2 in the XY plane, for example. Further, in some embodiments, the heating of the magnetic field generator 40-2 may cause the magnetic field generator 40-2 to be at a temperature exceeding a blocking temperature of the antiferromagnetic layer 41 included in the magnetic field generator 40-2. To the magnetic field generator 40-2 thus heated by irradiation with the laser light LR2, a magnetic field EM2 may be applied in a direction different from the Y-axis direction to thereby magnetize the magnetic field generator 40-2. The direction of the magnetic field EM2 may be a direction inclined toward the −X side by an angle θ2 with respect to the +Y direction as the reference direction, for example. The angle θ2 may be smaller in absolute value than the angle θ1. As a result, the magnetization direction M40-2 of the magnetic field generator 40-2 may be pinned substantially in the +Y direction. The laser light LR2 to be applied in pinning the magnetization direction M40-2 may be lower in intensity than the laser light to be applied in pinning the direction of the magnetization of the magnetization pinned layer 32 of each of the magnetic field detection elements 30.

The process of magnetizing the magnetic field generators 40-3 to 40-5 may be performed in a manner substantially similar to that of the magnetic field generator 40-1. Note, however, that the direction of the magnetic field to be applied to each of the magnetic field generators 40-3 to 40-5 may be allowed to substantially coincide with the +Y direction.

When performing the process of magnetizing the magnetic field generator 40-6, as illustrated in FIG. 2F, for example, laser light LR6 may be applied selectively to the magnetic field generator 40-6 alone to thereby heat the magnetic field generator 40-6, and a magnetic field EM6 may be applied to the magnetic field generator 40-6 in a direction different from the Y-axis direction. The direction of the magnetic field EM6 may be a direction inclined toward a +X side by an angle θ6 with respect to the +Y direction as the reference direction, for example. The angle θ6 may be substantially equal in absolute value to the angle θ2, for example. As a result, the magnetization direction M40-6 of the magnetic field generator 40-6 may be pinned substantially in the +Y direction.

When performing the process of magnetizing the magnetic field generator 40-7, as illustrated in FIG. 2G, for example, laser light LR7 may be applied selectively to the magnetic field generator 40-7 alone to thereby heat the magnetic field generator 40-7, and a magnetic field EM7 may be applied to the magnetic field generator 40-7 in a direction different from the Y-axis direction. The direction of the magnetic field EM7 may be a direction inclined toward the +X side by an angle θ7 with respect to the +Y direction as the reference direction, for example. The angle θ7 may be greater in absolute value than the angle θ6 and substantially equal in absolute value to the angle θ1, for example. As a result, the magnetization direction M40-7 of the magnetic field generator 40-7 positioned in the vicinity of the edge 20T2 of the lower magnetic yoke 20 may be pinned substantially in the +Y direction.

After magnetizing the magnetic field generators 40, processes including, for example, formation of the upper electrodes 62 and formation of the upper magnetic yoke 50 may be sequentially performed to complete the magnetic sensor 1.

### Workings and Example Effects of Magnetic Sensor 1

As described above, in the magnetic sensor 1 according to the present example embodiment, the respective magnetization directions M40 (M40-1 to M40-7) of the magnetic field generators 40 (40-1 to 40-7) arranged in the Y-axis direction, i.e., the direction in which the lower magnetic yoke 20 extends, are each inclined at less than 45 degrees with respect to the Y-axis direction. For example, the magnetization directions M40 (M40-1 to M40-7) may each substantially coincide with the Y-axis direction. This helps to allow the magnetic sensor 1 to accurately detect an intensity of the detection-target magnetic field in a predetermined direction, while achieving miniaturization.

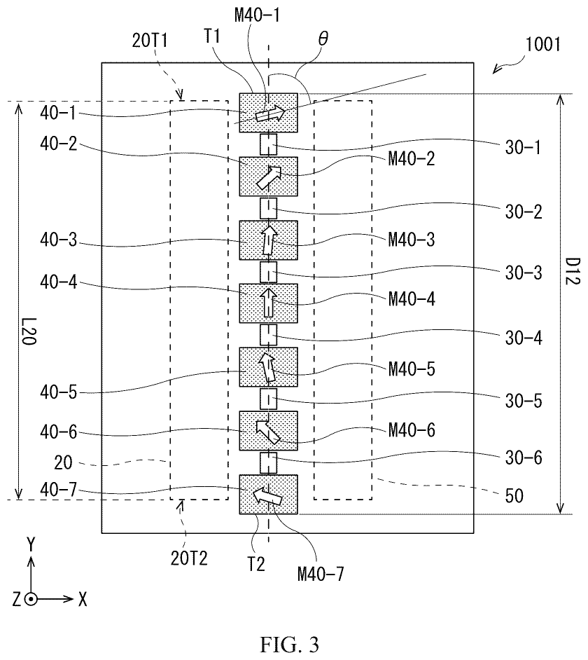

Suppose here a case where the magnetization direction M40 of any of the magnetic field generators 40 is inclined at 45 degrees or more with respect to the +Y direction, as in a magnetic sensor 1001 according to a reference example illustrated in FIG. 3 in which the magnetization directions M40-1, M40-2, M40-6, and M40-7 are inclined at such angles. In such a case, an initial direction of the magnetization M34 of the magnetization free layer 34 of each of the magnetic field detection elements 30-1 and 30-6 would also be greatly inclined with respect to the +Y direction. One reason for this is that such inclinations of the magnetization directions M40 result in a state where bias magnetic fields in directions different from the +Y direction by 45 degrees or more are applied by the magnetic field generators 40 to the magnetic field detection elements 30. For example, assume that when performing the process of magnetizing the magnetic field generators 40, the magnetic field generators 40 are collectively subjected to laser irradiation, with a magnetic field in the +Y direction being applied to each of the magnetic field generators 40. In such a case, due to the presence of the lower magnetic yoke 20, the angles θ, with respect to the +Y direction, of the magnetization directions M40-1 and M40-7 of the magnetic field generators 40-1 and 40-7 that are respectively positioned in the vicinity of the edges 20T1 and 20T2 of the lower magnetic yoke 20 would tend to become large enough to exceed 45 degrees. This would cause the initial direction of the magnetization M34 of the magnetization free layer 34 in each of the magnetic field detection elements 30-1 and 30-6 that are respectively positioned in the vicinity of the edges 20T1 and 20T2 of the lower magnetic yoke 20 to be greatly inclined with respect to the +Y direction. Accordingly, an error would occur in the electrical resistance value of each of the magnetic field detection elements 30-1 and 30-6 when the detection-target magnetic field is applied. This results in an error in an overall electrical resistance value of the multiple magnetic field detection elements 30 (30-1 to 30-6) that are included in the magnetic sensor 1 and coupled in series to each other. Note that increasing the length L20 of the lower magnetic yoke 20 in the Y-axis direction to sufficiently exceed the distance D12 between the first edge T1 of the magnetic field generator 40-1 and the second edge T2 of the magnetic field generator 40-7 could help to prevent the inclinations (i.e., the angles θ with respect to the +Y direction) of the magnetization directions M40 of the magnetic field generators 40 from reaching 45 degrees or more even if the process of magnetizing the magnetic field generators 40 is performed collectively. However, this leads to an increase in overall size of the magnetic sensor 1, thus making it difficult to achieve high density integration.

According to the method of manufacturing the magnetic sensor 1 of the present example embodiment, the process of heating the magnetic field generators 40 may be performed on an individual basis, while applying a magnetic field in a direction suitable for each of the magnetic field generators 40. This helps to allow the respective magnetization directions M40 (M40-1 to M40-7) of the magnetic field generators 40 to be closer to the +Y direction. In the magnetic sensor 1 of the present example embodiment manufactured by such a technique, inclinations of the respective magnetization directions M40 (M40-1 to M40-7) of the magnetic field generators 40 with respect to the +Y direction are reduced to less than 45 degrees. This helps to reduce an error of the electrical resistance value of each of the magnetic field detection elements 30 when the detection-target magnetic field is applied, which in turn helps to achieve accurate detection of the intensity of the detection-target magnetic field exerted on the magnetic sensor 1. Further, in the magnetic sensor 1 of the present example embodiment, as illustrated in FIG. 1B, the length L20 of the lower magnetic yoke 20 in the Y-axis direction may be less than or equal to the distance D12 over which a row of the magnetic field generators 40 arranged in the Y-axis direction extends. This helps to allow the magnetic sensor 1 to be small in dimension in the Y-axis direction. Such a configuration is suitable for higher density integration of the magnetic field detection elements 30.

Further, in the magnetic sensor 1 of the present example embodiment, the lower magnetic yoke 20 is provided adjacent to the magnetic field detection elements 30 in the X-axis direction. This helps to allow a direction of entry of the magnetic field line ML of the detection-target magnetic field into the magnetic sensor 1 to be deflected from the Z-axis direction to the X-axis direction, which in turn helps to allow the magnetic field detection elements 30 having sensitivity in the XY plane to detect the intensity of the detection-target magnetic field in the Z-axis direction.

In some embodiments, the length L30 of each of the magnetic field detection elements 30 in the Y-axis direction may be smaller than the length L40 of each of the magnetic field generators 40 in the Y-axis direction. This helps to allow the magnetic field detection elements 30 to achieve an increased linearity of changes in electrical resistance value versus changes in intensity of the detection-target magnetic field.

In some embodiments, the width W30 of each of the magnetic field detection elements 30 in the X-axis direction may be smaller than the width W40 of each of the magnetic field generators 40 in the X-axis direction. This helps to allow a highly homogeneous bias magnetic field to be applied to the whole of each of magnetic field detection elements 30, which in turn helps to achieve higher stability of the direction of the magnetization M34 of the magnetization free layer 34 of each of the magnetic field detection elements 30.

In some embodiments, a magnetic shield including a soft magnetic material such as permalloy (NiFe) may be used as the substrate 10. This helps to effectively prevent an unwanted disturbance magnetic field from being applied to the magnetic field detection elements 30, which in turn helps to allow the magnetic field detection elements 30 to achieve further improvement in accuracy of detection of the detection-target magnetic field.

### 2. Second Example Embodiment

### [Configuration of Magnetic Field Detection Unit 100]

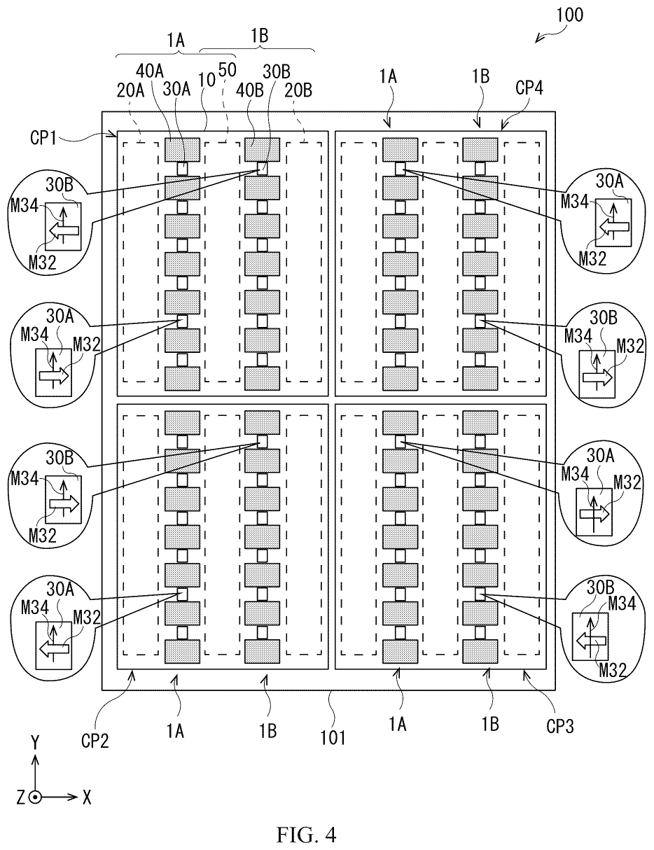

A description will now be given of a configuration of a magnetic field detection unit 100 according to a second example embodiment of the disclosure with reference to FIG. 4. FIG. 4 is a schematic plan diagram illustrating a plan configuration example of the magnetic field detection unit 100.

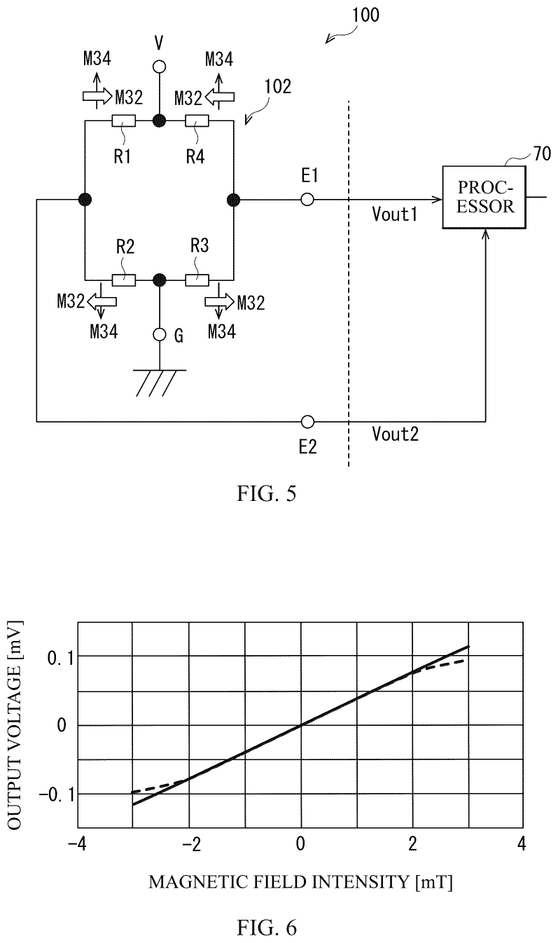

As illustrated in FIG. 4, the magnetic field detection unit 100 may include a support substrate 101 and multiple chips CP mounted on the support substrate 101. The configuration example of FIG. 4 illustrates an example case where four chips CP1 to CP4 are provided. The four chips CP1 to CP4 of the magnetic field detection unit 100 may be included in a magnetic field detection circuit 102 illustrated in FIG. 5. FIG. 5 is a circuit diagram illustrating a circuit configuration example of the magnetic field detection circuit 102 included in the magnetic field detection unit 100. Note that any embodiment of the disclosure is not limited to the configuration example of FIG. 4, and the number of the chips CP to be mounted on the support substrate 101 may be freely chosen.

The chips CP may each include two magnetic sensors 1A and 1B. The two magnetic sensors 1A and 1B may each have a configuration the same as the configuration of the magnetic sensor 1 described in relation to the first example embodiment, for example. However, in each of the chips CP, the two magnetic sensors 1A and 1B may share the substrate 10 and the upper magnetic yoke 50. Thus, each single substrate 10 may be provided with two lower magnetic yokes 20A and 20B, multiple magnetic field detection elements 30A, multiple magnetic field detection elements 30B, multiple magnetic field generators 40A, multiple magnetic field generators 40B, and the single upper magnetic yoke 50. The lower magnetic yoke 20A, the magnetic field detection elements 30A, and the magnetic field generators 40A may be components of the magnetic sensor 1A. The lower magnetic yoke 20B, the magnetic field detection elements 30B, and the magnetic field generators 40B may be components of the magnetic sensor 1B. The substrate 10 and the upper magnetic yoke 50 may be components of each of the two magnetic sensors 1A and 1B. In each of the chips CP, all the magnetic field detection elements 30A and 30B included in relevant one of the chips CP may be coupled in series to each other to configure a variable resistor. As used herein, the variable resistor refers to a device whose electrical resistance value changes in accordance with an intensity of a magnetic field component in a predetermined direction of an external magnetic field being applied.

To increase visibility, FIG. 4 illustrates the lower magnetic yokes 20A and 20B, the magnetic field detection elements 30A and 30B, the magnetic field generators 40A and 40B, and the single upper magnetic yoke 50 on each single substrate 10, and omits illustration of the other components.

In the chips CP1 and CP4, the magnetization directions M40 of the magnetic field generators 40A and 40B may all be along the +Y direction, for example. Accordingly, in the chips CP1 and CP4, the original directions of the magnetizations M34 of the magnetization free layers 34 of the magnetic field detection elements 30A and 30B may all be aligned in the +Y direction, for example. In contrast, in the chips CP2 and CP3, the magnetization directions M40 of the magnetic field generators 40A and 40B may all be along the −Y direction, for example. Accordingly, the original directions of the magnetizations M34 of the magnetization free layers 34 of the magnetic field detection elements 30A and 30B in the chips CP2 and CP3 may all be aligned in the −Y direction, for example.

In each of the chips CP1 and CP3, the directions of the magnetizations M32 of the magnetization pinned layers 32 in the magnetic field detection elements 30A and those in the magnetic field detection elements 30B may be pinned, for example, in the +X direction and the −X direction. respectively. For example, as illustrated in FIG. 4, in each of the chips CP1 and CP3, the direction of the magnetization M32 of the magnetization pinned layer 32 of each of the magnetic field detection elements 30A in the magnetic sensor 1A may be pinned in the +X direction, and the direction of the magnetization M32 of the magnetization pinned layer 32 of each of the magnetic field detection elements 30B in the magnetic sensor 1B may be pinned in the −X direction. In such a case, in each of the chips CP2 and CP4, the directions of the magnetizations M32 of the magnetization pinned layers 32 in the magnetic field detection elements 30A and those in the magnetic field detection elements 30B may be pinned, for example, in the −X direction and the +X direction. respectively. For example, as illustrated in FIG. 4, in each of the chips CP2 and CP4, the direction of the magnetization M32 of the magnetization pinned layer 32 of each of the magnetic field detection elements 30A in the magnetic sensor 1A may be pinned in the −X direction, and the direction of the magnetization M32 of the magnetization pinned layer 32 of each of the magnetic field detection elements 30B in the magnetic sensor 1B may be pinned in the +X direction.

In the magnetic field detection circuit 102 in FIG. 5, R1 represents a variable resistor as a collection of the magnetic field detection elements 30A and 30B in the chip CP1. Similarly, in the magnetic field detection circuit 102, R2 represents a variable resistor as an assembly of the magnetic field detection elements 30A and 30B in the chip CP2; R3 represents variable resistor as an assembly of the magnetic field detection elements 30A and 30B in the chip CP3; and R4 represents variable resistor as an assembly of the magnetic field detection elements 30A and 30B in the chip CP4.

The magnetic field detection unit 100 may detect the intensity of the detection-target magnetic field that is guided to each of the magnetic field detection elements 30 by being deflected to be along the X-axis direction by the lower magnetic yoke 20 and the upper magnetic yoke 50, for example. Assume here that the detection-target magnetic field is applied in the +Z direction to all the magnetic field detection elements 30 in each of the chips CP1 to CP4. In the magnetic field detection unit 100, a detection signal may be generated that corresponds to the intensity of the detection-target magnetic field.

As illustrated in FIG. 5, the magnetic field detection circuit 102 of the magnetic field detection unit 100 may configure a Wheatstone bridge. The magnetic field detection circuit 102 may include a power supply port V, a ground port G, two output ports E1 and E2, and first to fourth variable resistors R1 to R4. The first variable resistor R1 and the second variable resistor R2 may be coupled in series to each other. The third variable resistor R3 and the fourth variable resistor R4 may be coupled in series to each other. The first variable resistor R1 and the fourth variable resistor R4 may each have a first end coupled to the power supply port V. The first variable resistor R1 may have a second end coupled to a first end of the second variable resistor R2 and the output port E2. The fourth variable resistor R4 may have a second end coupled to a first end of the third variable resistor R3 and the output port E1. The second variable resistor R2 and the third variable resistor R3 may each have a second end coupled to the ground port G. A power supply voltage of a predetermined magnitude may be applied to the power supply port V. The ground port G may be coupled to a ground. The output ports E1 and E2 may each be coupled to a processor 70 provided outside. The processor 70 may include, for example, circuitry including a central processing unit (CPU) as an arithmetic processing unit, a read only memory (ROM), and a random access memory (RAM). The ROM may be a memory element that holds a program, a calculation parameter, etc., to be used by the CPU. The RAM may be a memory element that temporarily holds, for example, a parameter that changes as appropriate for execution by the CPU.

### Workings and Example Effects of Magnetic Field Detection Unit 100

The magnetic field detection unit 100 may output an output voltage that monotonously increases or decreases in accordance with the intensity of the detection-target magnetic field. A change in the intensity of the detection-target magnetic field may so change respective resistance values of the first to fourth variable resistors R1 to R4 as to increase the resistance values of the first and third variable resistors R1 and R3 and decrease the resistance values of the second and fourth variable resistors R2 and R4, or as to decrease the resistance values of the first and third variable resistors R1 and R3 and increase the resistance values of the second and fourth variable resistors R2 and R4. This may cause a change in potential difference between the output ports E1 and E2 illustrated in FIG. 5. The magnetic field detection unit 100 may generate a detection signal that depends on the potential difference between the output ports E1 and E2. The detection signal may have a correspondence with the intensity of the detection-target magnetic field. For example, the magnetic field detection unit 100 may exhibit a behavior as illustrated in a characteristic chart of FIG. 6. In FIG. 6, the horizontal axis represents the intensity of the detection-target magnetic field applied to the magnetic field detection elements 30 in the Z-axis direction, and the vertical axis represents the output voltage. In FIG. 6, the intensity of the detection-target magnetic field in the +Z direction is expressed in positive values, and the intensity of the detection-target magnetic field in the −Z direction is expressed in negative values. As indicated by a solid line in FIG. 6, the output voltage of the magnetic field detection unit 100 may change substantially linearly with changing intensity of the detection-target magnetic field being applied. In other words, the magnetic field detection unit 100 may exhibit an extremely high linearity in terms of relation between the intensity of the detection-target magnetic field and the output voltage. Note that a broken-line graph in FIG. 6 indicates a relation between the intensity of the detection-target magnetic field and the output voltage in a case where the magnetic field detection unit 100 includes the magnetic sensor 1001 according to the reference example illustrated in FIG. 3, instead of the magnetic sensors 1A and 1B. The magnetic field detection unit including the magnetic sensor 1001 would suffer degradation in the linearity of the relation between the intensity of the detection-target magnetic field and the output voltage, because of the magnetization directions M40 of some of the magnetic field generators 40 in the magnetic sensor 1001 being greatly inclined with respect to the +Y direction.

In the magnetic field detection unit 100 including the magnetic field detection circuit 102 configured as described above, the multiple chips CP may be provided that each include the magnetic sensors 1A and 1B. This helps to allow the magnetic field detection unit 100 to accurately detect the intensity of the detection-target magnetic field applied to the magnetic field detection unit 100.

### 3. Third Example Embodiment

### [Configuration of Magnetic Compass 200]

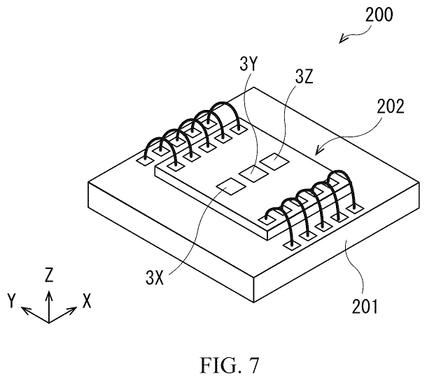

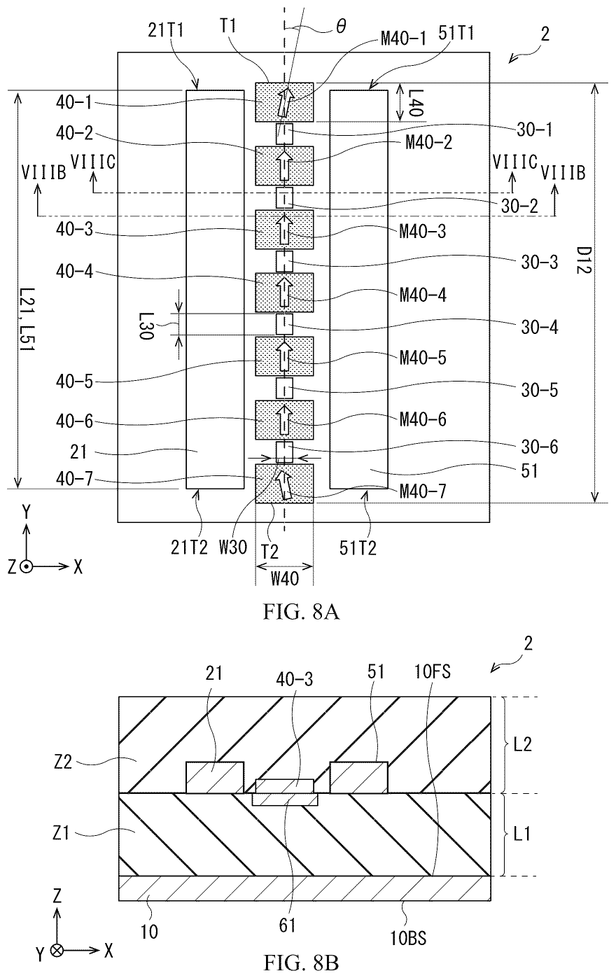

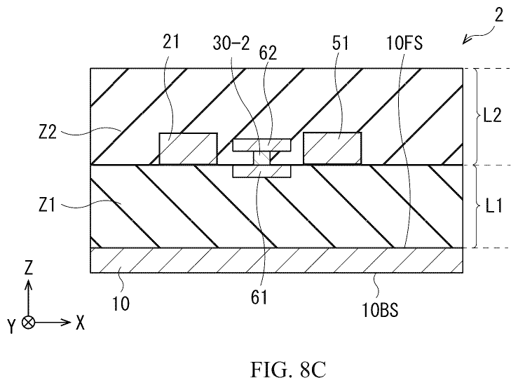

A description will now be given of a configuration of a magnetic compass 200 according to a third example embodiment of the disclosure with reference to FIGS. 7 and 8A to 8C. FIG. 7 is a perspective diagram illustrating an outer appearance of the magnetic compass 200. The magnetic compass 200 may include a chip 202 and a support substrate 201 supporting the chip 202. The chip 202 may include magnetic sensors 3X, 3Y, and 3Z. The magnetic compass 200 may be incorporated in a portable information terminal such as a smartphone. The magnetic sensor 3Z may have a configuration substantially the same as the configuration of the magnetic sensor 1 described in relation to the first example embodiment, for example. The magnetic sensors 3X and 3Y may each have a configuration of a magnetic sensor 2 illustrated in FIGS. 8A to 8C, for example. FIG. 8A is a plan diagram illustrating a plan configuration example of the magnetic sensor 2, and corresponds to FIG. 1A illustrating the plan configuration example of the magnetic sensor 1 described in relation to the first example embodiment. FIG. 8B is a cross-sectional diagram illustrating a cross-sectional configuration example of the magnetic sensor 2 as viewed in an arrowed direction along line VIIIB-VIIIB illustrated in FIG. 8A. FIG. 8C is a cross-sectional diagram illustrating the cross-sectional configuration example of the magnetic sensor 2 as viewed in an arrowed direction along line VIIIC-VIIIC illustrated in FIG. 8A. FIGS. 8B and 8C respectively correspond to FIGS. 1B and 1C illustrating the cross-sectional configuration example of the magnetic sensor 1 described in relation to the first example embodiment. The magnetic sensor 2 may include a first magnetic yoke 21 instead of the lower magnetic yoke 20 and include a second magnetic yoke 51 instead of the upper magnetic yoke 50. In the magnetic sensor 2, the first magnetic yoke 21 and the second magnetic yoke 51 may be provided in the same tier as that in which the magnetic field detection elements 30 and the magnetic field generators 40 are provided. For example, the first magnetic yoke 21, the second magnetic yoke 51, the magnetic field detection elements 30, and the magnetic field generators 40 may all be provided in the second tier L2. The magnetic sensor 2 may be otherwise substantially the same in configuration as the magnetic sensor 1. In the magnetic sensor 2, the distance D12 between the first edge T1 of the magnetic field generator 40-1 and the second edge T2 of the magnetic field generator 40-7 may be greater than or equal to a length L21 of the first magnetic yoke 21 in the Y-axis direction, and greater than or equal to a length L51 of the second magnetic yoke 51 in the Y-axis direction. In other words, the length L21 of the first magnetic yoke 21 and the length L51 of the second magnetic yoke 51 may each be less than or equal to the distance D12. The length L21 may be a length from a +Y-side edge 21T1 of the first magnetic yoke 21 to a −Y-side edge 21T2 of the first magnetic yoke 21. The length L51 may be a length from a +Y-side edge 51T1 of the second magnetic yoke 51 to a −Y-side edge 51T2 of the second magnetic yoke 51. The magnetic sensors 3X, 3Y, and 3Z may sense magnetic fields in directions different from each other. For example, in the magnetic compass 200, the magnetic sensor 3X, the magnetic sensor 3Y, and the magnetic sensor 3Z may be configured to respectively detect a first component, a second component, and a third component of an external magnetic field that are in three respective directions orthogonal to each other, such as an X-axis direction component, a Y-axis direction component, and a Z-axis direction component of the earth's magnetic field.

### Workings and Example Effects of Magnetic Compass 200

The magnetic compass 200 may include the magnetic sensor 3Z having substantially the same configuration as that of the magnetic sensor 1 described in relation to the first example embodiment, and the magnetic sensors 3X and 3Y each having the configuration of the magnetic sensor 2 illustrated in FIGS. 8A to 8C. The magnetic sensors 3X, 3Y, and 3Z may be configured to output their respective output signals that each have a high linearity, in accordance with the X-axis direction component, the Y-axis direction component, and the Z-axis direction component of the earth's magnetic field, respectively. This helps to allow the magnetic compass 200 to exhibit a higher detection resolution, which in turn helps to achieve highly reproducible measurement of a magnetic field.

### 4. Fourth Example Embodiment

### [Configuration of Imaging Apparatus 300]

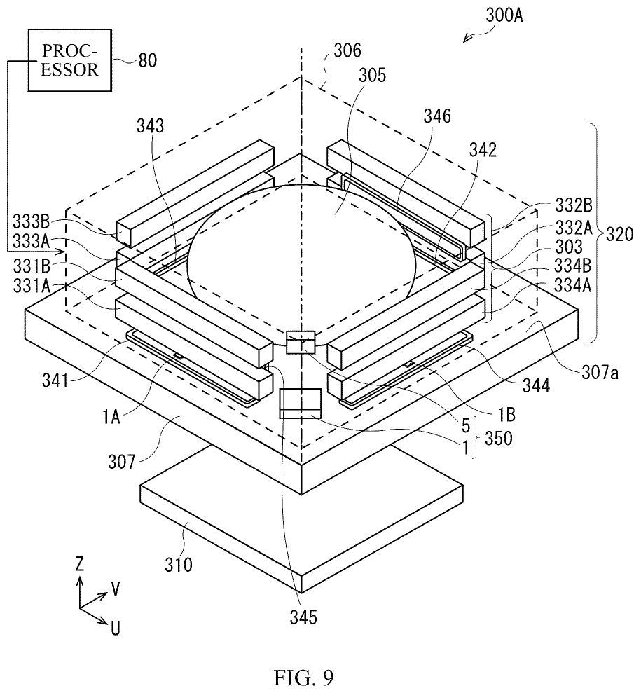

A description will now be given of a configuration of an imaging apparatus 300 according to a fourth example embodiment of the disclosure with reference to FIG. 9.

FIG. 9 is a perspective diagram illustrating an overall configuration example of the imaging apparatus 300. Note that the imaging apparatus 300 illustrated in FIG. 9 is merely exemplary. In any embodiment of the disclosure, components of the imaging apparatus 300 and their dimensions, shapes, and locations are not limited to those illustrated in FIG. 9.

The imaging apparatus 300 may constitute, for example, a part of a camera for a smartphone having an optical image stabilization mechanism and an autofocus mechanism. The imaging apparatus 300 may include an image sensor 310 and a lens module 320, for example. The Image sensor 310 may acquire an image by using a complementary metal-oxide semiconductor (CMOS), for example. The lens module 320 may guide light from a subject to the image sensor 310.

### [Configuration of Lens Module 320]

The lens module 320 may include a position detection unit 350, a drive unit 303, a lens 305, a housing 306, and a substrate 307. The position detection unit 350 includes the magnetic sensor 1 described in relation to the first example embodiment, and may include a magnet 5. The magnetic sensor 1 may be fixed to the substrate 307. The magnet 5 may be provided above the magnetic sensor 1, that is, positioned in the +Z direction with respect to the magnetic sensor 1. The magnet 5 may have a magnetization in the Z-axis direction, and may apply a magnetic field including a −Z direction component, for example, to the magnetic sensor 1. The magnet 5 may be configured to move together with the lens 305. Relative positions of the magnetic sensor 1 and the magnet 5 with respect to each other may change along the Z-axis direction. A change in the relative positions of the magnetic sensor 1 and the magnet 5 may cause a change in a detection signal of the magnetic sensor 1.

The position detection unit 350 may detect a position of the lens 305 when performing automatic focusing or performing optical image stabilization. The drive unit 303 may move the lens 305. The housing 306 may accommodate and protect the position detection unit 350, the drive unit 303, and the lens 305. The substrate 307 may support the position detection unit 350, the drive unit 303, the lens 305, and the housing 306.

Here, a +U direction and a +V direction will be defined based on FIG. 9. The +U direction is a direction rotated by −45 degrees from the +X direction toward the −−Y direction. The +V direction is a direction rotated by 45 degrees from the +X direction toward the +Y direction. The +U direction and the +V direction are each orthogonal to the +Z direction. For the lens module 320, the +Z direction is a direction perpendicular to a top surface 307a of the substrate 307 and from the substrate 307 toward the lens 305. Both the +U direction and the +V direction are parallel to the top surface 307a of the substrate 307. Further, a direction opposite to the +U direction will be denoted as a −U direction, and a direction opposite to the +V direction will be denoted as a −V direction. The lens 305 may be disposed above the top surface 307a of the substrate 307, being so oriented that an optical axis of the lens 305 is parallel to the Z-axis direction. The substrate 307 may have an opening to allow light having passed through the lens 305 to pass through the opening. The lens module 320 may be in alignment with the image sensor 310 to allow the light having passed through the lens 305 and the opening of the substrate 307 to enter the image sensor 310.

The drive unit 303 may include magnets 331A, 331B, 332A, 332B, 333A, 333B, 334A, 334B, and coils 341, 342, 343, 344, 345, and 346. The magnet 331A may be positioned in the −V direction as viewed from the lens 305. The magnet 332A may be positioned in the +V direction as viewed from the lens 305. The magnet 333A may be positioned in the −U direction as viewed from the lens 305. The magnet 334A may be positioned in the +U direction as viewed from the lens 305. The magnets 331B, 332B, 333B, and 334B may be positioned above (i.e., positioned on the +Z side relative to) the magnets 331A, 332A, 333A, and 334A, respectively.

The magnets 331A, 331B, 332A, and 332B may each have a rectangular parallelepiped shape that is long in a U-axis direction. The magnets 333A, 333B, 334A, and 334B may each have a rectangular parallelepiped shape that is long in a V-axis direction. The magnets 331A and 332B may each have a magnetization in the +V direction. The magnets 331B and 332A may each have a magnetization in the −V direction. The magnets 333A and 334B may each have a magnetization in the +U direction. The magnets 333B and 334A may each have a magnetization in the −U direction.

The coil 341 may be disposed between the magnet 331A and the substrate 307. The coil 342 may be disposed between the magnet 332A and the substrate 307. The coil 343 may be disposed between the magnet 333A and the substrate 307. The coil 344 may be disposed between the magnet 334A and the substrate 307. The coil 345 may be disposed between the lens 305 and the magnets 331A and 331B. The coil 346 may be disposed between the lens 305 and the magnets 332A and 332B. The coils 341, 342, 343, and 344 may be fixed to the substrate 307. The coils 345 and 346 may be configured to move together with the lens 305 along the Z-axis direction.

The coil 341 may be subjected to a magnetic field generated from the magnet 331A. The coil 342 may be subjected to a magnetic field generated from the magnet 332A. The coil 343 may be subjected to a magnetic field generated from the magnet 333A. The coil 344 may be subjected to a magnetic field generated from the magnet 334A.

The coil 345 may include a part to be subjected to a +V direction component of the magnetic field generated from the magnet 331A and a part to be subjected to a −V direction component of a magnetic field generated from the magnet 331B. The coil 346 may include a part to be subjected to a −V direction component of the magnetic field generated from the magnet 332A and a part to be subjected to a +V direction component of a magnetic field generated from the magnet 332B.

The drive unit 303 may further include the magnetic sensor 1A positioned on an inner side of the coil 341 and fixed to the substrate 307, and the magnetic sensor 1B positioned on an inner side of the coil 344 and fixed to the substrate 307. The magnetic sensors 1A and 1B may be used to change the position of the lens 305 in order to reduce an influence of a hand-induced apparatus shake. The magnetic sensor 1A may detect the magnetic field generated from the magnet 331A and generate a signal corresponding to the position of the magnet 331A. The magnetic sensor 1B may detect the magnetic field generated from the magnet 334A and generate a signal corresponding to the position of the magnet 334A. The magnetic sensor 1 described in relation to the first example embodiment may be used as each of the magnetic sensors 1A and 1B.

The optical image stabilization mechanism may be configured to detect the hand-induced apparatus shake through the use of, for example, a sensor such as a gyro sensor. The sensor such as the gyro sensor may be provided outside the imaging apparatus 300. When the optical image stabilization mechanism has detected the hand-induced apparatus shake, a processor 80 may control the drive unit 303 to change the relative position of the lens 305 with respect to the substrate 307 in accordance with a mode of the apparatus shake. This helps to stabilize the absolute position of the lens 305 and to thereby reduce the influence of the apparatus shake. Note that the relative position of the lens 305 with respect to the substrate 307 may change either in a direction parallel to the U-axis direction or in a direction parallel to the V-axis direction, depending on the mode of the apparatus shake.

### [Operation of Imaging Apparatus 300]

Operation of the imaging apparatus 300 may be controlled by the processor 80 provided outside the imaging apparatus 300. The processor 80 may include, for example, circuitry including a central processing unit (CPU) as an arithmetic processing unit, a read only memory (ROM), and a random access memory (RAM). The ROM may be a memory element that holds a program, a calculation parameter, etc., to be used by the CPU. The RAM may be a memory element that temporarily holds, for example, a parameter that changes as appropriate for execution by the CPU.

The autofocus mechanism may be configured to detect an in-focus state of a subject through the use of, for example, a sensor such as the image sensor 310 or an autofocus sensor. The processor 80 may cause the drive unit 303 to change the relative position of the lens 305 with respect to the substrate 307 along the Z-axis direction to thereby bring the subject into focus. This helps to allow for automatic focusing on the subject. For example, when moving the relative position of the lens 305 with respect to the substrate 307 in the +Z direction, the processor 80 may cause respective currents to be passed through the coils 345 and 346 in predetermined directions. These currents and the respective magnetic fields generated from the magnets 331A, 331B, 332A, and 332B may cause a Lorentz force in the +Z direction to be exerted on each of the coils 345 and 346. As a result, the coils 345 and 346 may move together with the lens 305 in the +Z direction with respect to the substrate 307. When moving the relative position of the lens 305 with respect to the substrate 307 in the −Z direction, the processor 80 may cause respective currents to be passed through the coils 345 and 346 in directions opposite to those in the above-described case of moving the relative position in the +Z direction.

Next, a description will be given of an operation of the drive unit 303 in relation to the optical image stabilization mechanism. Upon passage of currents through the coils 341 and 342 by the processor 80, the magnetic fields generated from the magnets 331A and 332A and magnetic fields generated from the coils 341 and 342 may interact with each other to cause the magnets 331A and 332A to move together with the lens 305 in a direction parallel to the V-axis direction with respect to the substrate 307. Further, upon passage of currents through the coils 343 and 344 by the processor 80, the magnetic fields generated from the magnets 333A and 334A and magnetic fields generated from the coils 343 and 344 may interact with each other to cause the magnets 333A and 334A to move together with the lens 305 in a direction parallel to the U-axis direction with respect to the substrate 307. The processor 80 may detect the position of the lens 305 by measuring the respective signals that are generated by the magnetic sensors 1A and 1B and correspond to the positions of the magnets 331A and 334A.

### Workings and Example Effects of Imaging Apparatus 300

The imaging apparatus 300 may include the position detection unit 350 including the magnetic sensor 1 according to the foregoing first example embodiment. This helps to allow the imaging apparatus 300 to accurately detect the amount of change or amount of displacement of the position of the magnet 5 that moves together with the lens 305, which in turn helps to allow the imaging apparatus 300 to perform focusing with high accuracy. Further, the imaging apparatus 300 may include the drive unit 303 including the magnetic sensors 1A and 1B to each of which the magnetic sensor 1 of the foregoing first example embodiment is applicable. This helps to allow the imaging apparatus 300 to accurately detect the amount of change or amount of displacement of the position of each the magnets 331A and 334A that each move together with the lens 305, which in turn helps to allow the imaging apparatus 300 to perform optical image stabilization with high accuracy.

The imaging apparatus 300 may include either one of the autofocus mechanism or the optical image stabilization mechanism.

### 7. Other Modification Examples

Although some example embodiments of the disclosure have been described hereinabove, the disclosure is not limited to such example embodiments, and may be modified in a variety of ways. For example, in the foregoing first example embodiment, the exchange-coupled bias structure in which the antiferromagnetic layer and the ferromagnetic layer are exchange-coupled to each other has been described as an example of the magnetic field generator that applies a bias magnetic field to each of the magnetic field detection elements; however, the magnetic field generator according to an embodiment of the disclosure may take any other suitable form. In some embodiments, the magnetic field generator may be a permanent magnet, for example. Non-limiting examples of a material of the permanent magnet may include a neodymium-based magnet material such as NdFeB and a rare-earth magnet material such as SmCo.

Further, in some embodiments, the magnetic sensor may include an additional magnetic shield positioned above the upper magnetic yoke.

In the magnetic field detection unit 100 according to the foregoing second example embodiment, the two magnetic sensors 1A and 1B in each of the chips CP may share the upper magnetic yoke 50; however, embodiments of the disclosure are not limited thereto. In some embodiments, the two magnetic sensors in each of the chips of the magnetic field detection unit may share the lower magnetic yoke. In some embodiments, the magnetic field detection unit may have a structure in which the two magnetic sensors 1A and 1B do not share any of their components. Further, in some embodiments, some of the magnetic field generators 40A included in the magnetic sensor 1A and some of the magnetic field generators 40B included in the magnetic sensor 1B in the magnetic field detection unit 100 may be collectively subjected to the magnetizing process.

Dimensions, layout, etc. of the components described herein are merely illustrative and non-limiting.

Further, the position detection unit according to any embodiment of the disclosure is not limited to a detection unit intended to detect the position of a lens, and may be a detection unit intended to detect a spatial position of any object other than a lens.

The disclosure encompasses any possible combination of some or all of the various embodiments and their modification examples described herein and incorporated herein. It is possible to achieve at least the following configurations from the foregoing example embodiments and modification examples of the disclosure.

(1)

A magnetic sensor including
a stacked structure including a first tier and a second tier, the first tier including a magnetic yoke, the second tier including a magnetic field detection element and magnetic field generators, the magnetic field generators being disposed discretely along a first-axis direction and each applying a magnetic field to the magnetic field detection element, the first tier and the second tier being stacked in order in a second-axis direction intersecting the first-axis direction, in which
the magnetic field detection element is interposed between two of the magnetic field generators in the first-axis direction,
the magnetic yoke extends in the first-axis direction, and is adjacent to the magnetic field detection element in a third-axis direction in a plan view as viewed in the second-axis direction, the third-axis direction intersecting both the first-axis direction and the second-axis direction, and
respective magnetization directions of the magnetic field generators are each inclined at less than 45 degrees with respect to the first-axis direction.
   (2)

The magnetic sensor according to (1), in which the magnetic field generators each include an exchange-coupled bias structure including a ferromagnetic body and an antiferromagnetic body, the antiferromagnetic body being in contact with and exchange-coupled to the ferromagnetic body.

(3)

The magnetic sensor according to (1), in which
the magnetic field generators disposed discretely along the first-axis direction include:
   a first magnetic field generator disposed at a first end in the first-axis direction; and
   a second magnetic field generator disposed at a second end in the first-axis direction, the second end being opposite to the first end, and
a distance between a first edge and a second edge is greater than or equal to a length of the magnetic yoke in the first-axis direction, the first edge being an edge, of the first magnetic field generator, that is positioned farthest from the second magnetic field generator, the second edge being an edge, of the second magnetic field generator, that is positioned farthest from the first magnetic field generator.
   (4)

The magnetic sensor according to (1), in which a length of the magnetic field detection element in the first-axis direction is smaller than a length of each of the magnetic field generators in the first-axis direction.

(5)

The magnetic sensor according to (1), in which a width of the magnetic field detection element in the third-axis direction is smaller than a width of each of the magnetic field generators in the third-axis direction.

(6)

The magnetic sensor according to (1), further including a support that supports the stacked structure.

(7)

The magnetic sensor according to (6), in which the support includes a magnetic shield.

(8)

The magnetic sensor according to (1), in which the magnetic field detection element includes a magnetoresistive effect element including a stack in which a magnetization pinned layer, a gap layer, and a magnetization free layer are stacked in order.

(9)

A magnetic sensor including:
a magnetic yoke;
a magnetic field detection element; and
magnetic field generators that are disposed discretely along a first-axis direction and each apply a magnetic field to the magnetic field detection element, in which
the magnetic field detection element is interposed between two of the magnetic field generators in the first-axis direction,
the magnetic field generators each include an exchange-coupled bias structure including a ferromagnetic body and an antiferromagnetic body, the antiferromagnetic body being in contact with and exchange-coupled to the ferromagnetic body,
the magnetic yoke extends in the first-axis direction, and
respective magnetization directions of the magnetic field generators are each inclined at less than 45 degrees with respect to the first-axis direction.
   (10)

A magnetic field detection unit including the magnetic sensor according to any one of (1) to (9).

(11)

A position detection unit including the magnetic sensor according to any one of (1) to (9).

(12)

A lens module including the magnetic sensor according to any one of (1) to (9).

(13)

An imaging apparatus including the lens module according to (12).

(14)

A method of manufacturing a magnetic sensor, including:
forming a magnetic yoke extending in a first-axis direction;
forming a magnetic field detection element;
forming a first magnetic field generator and a second magnetic field generator to be each positioned adjacent to the magnetic yoke in a second-axis direction intersecting the first-axis direction, and to allow the magnetic field detection element to be interposed between the first magnetic field generator and the second magnetic field generator in the first-axis direction;
magnetizing the first magnetic field generator by applying a first magnetic field to the first magnetic field generator in a first magnetization direction different from the first-axis direction, while heating the first magnetic field generator by applying first laser light selectively to the first magnetic field generator alone, of the first and second magnetic field generators; and
magnetizing the second magnetic field generator by applying a second magnetic field to the second magnetic field generator in a second magnetization direction different from the first magnetization direction, while heating the second magnetic field generator by applying second laser light selectively to the second magnetic field generator alone, of the first and second magnetic field generators.
   (15)

The method according to (14), in which
the first magnetic field generator and the second magnetic field generator each include an exchange-coupled bias structure including a ferromagnetic body and an antiferromagnetic body, the antiferromagnetic body being in contact with and exchange-coupled to the ferromagnetic body,
when performing the magnetizing of the first magnetic field generator, the heating of the first magnetic field generator by applying the first laser light is performed to cause the first magnetic field generator to be at a temperature exceeding a blocking temperature of the antiferromagnetic body included in the first magnetic field generator, and
when performing the magnetizing of the second magnetic field generator, the heating of the second magnetic field generator by applying the second laser light is performed to cause the second magnetic field generator to be at a temperature exceeding a blocking temperature of the antiferromagnetic body included in the second magnetic field generator.

A magnetic sensor and a method of manufacturing the magnetic sensor, and a magnetic field detection unit, a position detection unit, a lens module, and an imaging apparatus according to at least one embodiment of the disclosure each make it possible to accurately detect a magnetic field in a predetermined direction, while achieving miniaturization.

It is to be noted that the effects of the disclosure should not be limited thereto, and may be any of the effects described herein.

Although the disclosure has been described hereinabove in terms of the example embodiment and modification examples, the disclosure is not limited thereto. It should be appreciated that variations may be made in the described example embodiment and modification examples by those skilled in the art without departing from the scope of the disclosure as defined by the following claims.

The limitations in the claims are to be interpreted broadly based on the language employed in the claims and not limited to examples described in this specification or during the prosecution of the application, and the examples are to be construed as non-exclusive.

As used in this specification and the appended claims, the singular forms “a,” “an,” and “the” include, especially in the context of the claims, are to be construed to cover both the singular and the plural, unless otherwise indicated herein or clearly contradicted by context.

Throughout this specification and the appended claims, unless the context requires otherwise, the terms “comprise”, “include”, “have”, and their variations are to be construed to cover the inclusion of a stated element, integer or step but not the exclusion of any other non-stated element, integer or step.

The use of the terms first, second, etc. do not denote any order or importance, but rather the terms first, second, etc. are used to distinguish one element from another.

The term “substantially”, “approximately”, “about”, and its variants having the similar meaning thereto are defined as being largely but not necessarily wholly what is specified as understood by one of ordinary skill in the art.

The term “disposed on/provided on/formed on” and its variants having the similar meaning thereto as used herein refer to elements disposed directly in contact with each other or indirectly by having intervening structures therebetween.

The invention claimed is:

1. A magnetic sensor comprising
a stacked structure including a first tier and a second tier, the first tier including a magnetic yoke, the second tier including a magnetic field detection element and magnetic field generators, the magnetic field generators being disposed discretely along a first-axis direction and each applying a magnetic field to the magnetic field detection element, the first tier and the second tier being stacked in order in a second-axis direction intersecting the first-axis direction, wherein
the magnetic field detection element is interposed between two of the magnetic field generators in the first-axis direction,
the magnetic yoke extends in the first-axis direction, and is adjacent to the magnetic field detection element in a third-axis direction in a plan view as viewed in the second-axis direction, the third-axis direction intersecting both the first-axis direction and the second-axis direction, and
respective magnetization directions of the magnetic field generators are each inclined at less than 45 degrees with respect to the first-axis direction.

2. The magnetic sensor according to claim 1, wherein the magnetic field generators each comprise an exchange-coupled bias structure including a ferromagnetic body and an antiferromagnetic body, the antiferromagnetic body being in contact with and exchange-coupled to the ferromagnetic body.

3. The magnetic sensor according to claim 1, wherein
the magnetic field generators disposed discretely along the first-axis direction include:
a first magnetic field generator disposed at a first end in the first-axis direction; and
a second magnetic field generator disposed at a second end in the first-axis direction, the second end being opposite to the first end, and
a distance between a first edge and a second edge is greater than or equal to a length of the magnetic yoke in the first-axis direction, the first edge being an edge, of the first magnetic field generator, that is positioned farthest from the second magnetic field generator, the second edge being an edge, of the second magnetic field generator, that is positioned farthest from the first magnetic field generator.

4. The magnetic sensor according to claim 1, wherein a length of the magnetic field detection element in the first-axis direction is smaller than a length of each of the magnetic field generators in the first-axis direction.

5. The magnetic sensor according to claim 1, wherein a width of the magnetic field detection element in the third-axis direction is smaller than a width of each of the magnetic field generators in the third-axis direction.

6. The magnetic sensor according to claim 1, further comprising a support that supports the stacked structure.

7. The magnetic sensor according to claim 6, wherein the support comprises a magnetic shield.

8. The magnetic sensor according to claim 1, wherein the magnetic field detection element comprises a magnetoresistive effect element including a stack in which a magnetization pinned layer, a gap layer, and a magnetization free layer are stacked in order.

9. A magnetic field detection unit comprising the magnetic sensor according to claim 1.

10. A position detection unit comprising the magnetic sensor according to claim 1.

11. A lens module comprising the magnetic sensor according to claim 1.

12. An imaging apparatus comprising the lens module according to claim 11.

13. A magnetic sensor comprising:
a magnetic yoke;
a magnetic field detection element; and
magnetic field generators that are disposed discretely along a first-axis direction and each apply a magnetic field to the magnetic field detection element, wherein
the magnetic field detection element is interposed between two of the magnetic field generators in the first-axis direction,
the magnetic field generators each comprise an exchange-coupled bias structure including a ferromagnetic body and an antiferromagnetic body, the antiferromagnetic body being in contact with and exchange-coupled to the ferromagnetic body,
the magnetic yoke extends in the first-axis direction, and
respective magnetization directions of the magnetic field generators are each inclined at less than 45 degrees with respect to the first-axis direction.

14. A magnetic field detection unit comprising the magnetic sensor according to claim 13.

15. A position detection unit comprising the magnetic sensor according to claim 13.

16. A lens module comprising the magnetic sensor according to claim 13.

17. An imaging apparatus comprising the lens module according to claim 16.

18. A method of manufacturing a magnetic sensor, comprising:
forming a magnetic yoke extending in a first-axis direction;
forming a magnetic field detection element;
forming a first magnetic field generator and a second magnetic field generator to be each positioned adjacent to the magnetic yoke in a second-axis direction intersecting the first-axis direction, and to allow the magnetic field detection element to be interposed between the first magnetic field generator and the second magnetic field generator in the first-axis direction;
magnetizing the first magnetic field generator by applying a first magnetic field to the first magnetic field generator in a first magnetization direction different from the first-axis direction, while heating the first magnetic field generator by applying first laser light selectively to the first magnetic field generator alone, of the first and second magnetic field generators; and
magnetizing the second magnetic field generator by applying a second magnetic field to the second magnetic field generator in a second magnetization direction different from the first magnetization direction, while heating the second magnetic field generator by applying second laser light selectively to the second magnetic field generator alone, of the first and second magnetic field generators.

19. The method according to claim 18, wherein
the first magnetic field generator and the second magnetic field generator each comprise an exchange-coupled bias structure including a ferromagnetic body and an antiferromagnetic body, the antiferromagnetic body being in contact with and exchange-coupled to the ferromagnetic body,
when performing the magnetizing of the first magnetic field generator, the heating of the first magnetic field generator by applying the first laser light is performed to cause the first magnetic field generator to be at a temperature exceeding a blocking temperature of the antiferromagnetic body included in the first magnetic field generator, and
when performing the magnetizing of the second magnetic field generator, the heating of the second magnetic field generator by applying the second laser light is performed to cause the second magnetic field generator to be at a temperature exceeding a blocking temperature of the antiferromagnetic body included in the second magnetic field generator.
